(19) United States
(12) Patent Application Publication
(10) Pub. No.: US 2024/0256727 A1
(43) Pub. Date: Aug. 1, 2024

(54) SYSTEMS, APPARATUS, ARTICLES OF MANUFACTURE, AND METHODS FOR MACHINE-LEARNING BASED HOLE PLUG VALIDATION

(71) Applicant: The Boeing Company, Arlington, VA (US)

(72) Inventors: Seema Chopra, Bengaluru (IN); Ganesha P. Saralikana, Bengaluru (IN); Chandrashekhar, Bengaluru (IN); Adarsh Vittal Shetty, Bengaluru (IN); SK Sahariyaz Zaman, Bengaluru (IN)

(21) Appl. No.: 18/155,001

(22) Filed: Jan. 16, 2023

(51) Int. Cl. G06F 30/15; G06F 30/27

(52) U.S. Cl. CPC G06F 30/15; G06F 30/27

(57) ABSTRACT

Systems, articles of manufacture, apparatus, and methods are disclosed for machine-learning based hole plug validation. An example apparatus includes at least one memory, machine-readable instructions, and processor circuitry to at least one of execute or instantiate the machine-readable instructions to at least execute a machine-learning model based on an image of an aircraft component to generate an output representative of first identifications of first hole plugs in the aircraft component. The processor circuitry is further to determine one or more differences between the first identifications of the first hole plugs in the image and second identifications of second hole plugs in a reference model of the aircraft component. Additionally, the processor circuitry is to cause an operation associated with an aircraft to occur based on the one or more differences.

### FIELD OF THE DISCLOSURE

This disclosure relates generally to machine learning and, more particularly, to systems, apparatus, articles of manufacture, and methods for machine-learning based hole plug validation.

### BACKGROUND

In recent years, Full Size Determinant Assembly (FSDA) is becoming increasingly utilized in manufacturing processes to assemble structures without holding fixtures. FSDA includes designing parts that fit together at a pre-defined interface and do not require holding fixtures, setting gauges, or other complex adjustments and measurements. For instance, full size holes may be drilled into a component prior to being coupled to another component. Such full-size holes may need to be plugged prior to subsequent manufacturing processes to avoid unintended consequences.

### BRIEF DESCRIPTION OF THE DRAWINGS

FIG. 1 is an illustration of an example component verification system including an example component verification device that at least one of executes or instantiates a machine-learning model to validate hole plug placement for aircraft components.

FIG. 2 is a block diagram of an example implementation of the component verification device of FIG. 1.

FIG. 3 is a block diagram of a first example workflow to implement the example component verification system of FIG. 1.

FIG. 4 is a block diagram of a second example workflow to implement the example component verification system of FIG. 1.

FIG. 5 is an illustration of an example aircraft including example doublers.

FIG. 6 is an illustration of one of the example doublers of FIG. 5 without hole plugs.

FIG. 7 is an illustration of the example doubler of FIG. 6 with hole plugs.

FIG. 8 is a block diagram of a third example workflow to validate hole plug placement for an aircraft component.

FIG. 9 is a flowchart representative of example machine readable instructions and/or example operations that may be executed by example processor circuitry to implement the example component verification circuitry of FIG. 2 to validate hole plug placement for an aircraft component.

FIG. 10 is another flowchart representative of example machine readable instructions and/or example operations that may be executed by example processor circuitry to implement the example component verification circuitry of FIG. 2 to validate hole plug placement for an aircraft component.

FIG. 11 is a flowchart representative of example machine readable instructions and/or example operations that may be executed by example processor circuitry to implement the example component verification circuitry of FIG. 2 to compare hole plugs in an image and a reference model.

FIG. 12 is a flowchart representative of example machine readable instructions and/or example operations that may be executed by example processor circuitry to implement the example component verification circuitry of FIG. 2 to train a machine-learning model to validate hole plug placement for an aircraft component.

FIG. 13 is a block diagram of an example processing platform including processor circuitry structured to execute the example machine readable instructions and/or the example operations of FIGS. 9-12 to implement the example component verification circuitry of FIG. 2.

FIG. 14 is a block diagram of an example implementation of the processor circuitry of FIG. 13.

FIG. 15 is a block diagram of another example implementation of the processor circuitry of FIG. 13.

FIG. 16 is a block diagram of an example software distribution platform (e.g., one or more servers) to distribute software (e.g., software corresponding to the example machine readable instructions of FIGS. 9-12) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

### SUMMARY

Systems, apparatus, articles of manufacture, and methods for machine-learning based hole plug validation are disclosed.

An example apparatus is disclosed that includes at least one memory, machine-readable instructions, and processor circuitry to at least one of execute or instantiate the machine-readable instructions to at least execute a machine-learning model based on an image of an aircraft component to generate an output representative of first identifications of first hole plugs in the aircraft component. The processor circuitry is further to determine one or more differences between the first identifications of the first hole plugs in the image and second identifications of second hole plugs in a reference model of the aircraft component. Additionally, the processor circuitry is to cause an operation associated with an aircraft to occur based on the one or more differences.

An example at least one non-transitory computer readable storage medium is disclosed that includes instructions that, when executed, cause processor circuitry to at least execute a machine-learning model based on an image of an aircraft component to generate an output representative of first identifications of first hole plugs in the aircraft component, determine one or more differences between the first identifications of the first hole plugs in the image and second identifications of second hole plugs in a reference model of the aircraft component, and cause an operation associated with an aircraft to occur based on the one or more differences.

An example method is disclosed that includes executing a machine-learning model based on an image of an aircraft component to generate an output representative of first identifications of first hole plugs in the aircraft component, determining one or more differences between the first identifications of the first hole plugs in the image and second identifications of second hole plugs in a reference model of the aircraft component, and causing an operation associated with an aircraft to occur based on the one or more differences.

### DETAILED DESCRIPTION

In general, the same reference numbers will be used throughout the drawing(s) and accompanying written description to refer to the same or like parts. The figures are not to scale.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein “substantially real time” and “substantially real-time” refer to occurrence in a near instantaneous manner recognizing there may be real-world delays for computing time, transmission, etc. Thus, unless otherwise specified, “substantially real time” and “substantially real-time” refer to being within a 1-second time frame of real time.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

Full Size Determinant Assembly (FSDA) is becoming prevalent in manufacturing processes to assemble structures without utilizing holding fixtures. FSDA includes designing components or parts that fit together at a pre-defined interface and do not require holding fixtures, setting gauges, or other complex adjustments and measurements. In some prior manufacturing processes involving a coupling together of two mechanical components, a manufacturing operator drills small initial or pilot holes into the two mechanical components at locations where the two mechanical components are to be coupled. The two mechanical components are slotted into a holding fixture. Once the two mechanical components are lined up and held rigidly in place, the manufacturing operator drills full-sized holes. Accordingly, some such prior manufacturing processes require a time-consuming process of: making the pilot holes; placing the mechanical components into the holding fixture; verifying their alignment; drilling the full-sized holes; removing the mechanical components from the holding fixture; verifying that the full-sized holes are clean and properly sized; reassembling the mechanical components together; and fastening them together into a mechanical structure or assembly.

FSDA may achieve a reduction in time required to manufacture structures. With respect to the above example, FSDA may be employed by drilling full-sized holes into the mechanical components prior to being coupled together. However, such full-sized holes may need to be covered, masked, plugged, sealed, etc., prior to subsequent manufacturing processes to avoid unintended consequences such as damaging the mechanical components or causing undesirable electrical operation of a larger assembly or system. For example, prior to coupling the mechanical components together, a subsequent manufacturing process of chemically treating the mechanical components may be performed, such as anodizing and/or painting the mechanical components. In some instances, if chemicals erroneously coat the interiors of uncovered full-sized holes, then the couplings at the locations of the uncovered full-sized holes may not provide a sufficient electrical grounding path if the full-sized holes are used for that purpose. In some instances, chemical depositions in the interiors of the full-sized holes may damage the mechanical components or cause premature failures.

In some instances, the full-sized holes are covered, masked, or filled to prevent such erroneous chemical depositions. For example, the full-sized holes may be filled with hole plugs (e.g., hole plugs made or composed of soft or pliable material(s)). In some instances, the hole plugs have different colors to visually identify different hole diameters. Prior to proceeding with a subsequent manufacturing process, manufacturing personnel may manually verify that the correct number and/or colors of hole plugs are used. However, such manual verifications consume a substantial number of man hours (e.g., 1-2 man hours per component of simple complexity, 2-4 man hours per component of medium complexity, 4-10 man hours per component of complex complexity, etc.) and thereby substantially reduce manufacturing efficiency and increase lead times of producing mechanical components. In some instances, the manual verifications may miss uncovered full-sized holes and may therefore cause subsequent issues during later manufacturing processes, testing, or real-world operation.

Systems, apparatus, articles of manufacture, and methods for machine-learning based hole plug validation are disclosed. Examples disclosed herein include execution of image-processing machine-learning models and implementation of natural language processing techniques for hole plug placement validations. In some disclosed examples, a machine-learning model ingests an image of a component, such as an aircraft component (or any other vehicle component, such as a land-based vehicle component, a marine-based vehicle component, etc.), and identifies a number and/or a color of respective hole plugs in the image. In some disclosed examples, discrepancies between the number of identified hole plugs and/or color(s) thereof may be identified based on comparisons with respect to a reference model (e.g., a computer-aided design (CAD) model) of the component. In some disclosed examples, the component may be validated as having the correct number and/or color(s) of hole plugs. For example, the component may proceed to undergo subsequent manufacturing processes, which can include chemical depositions. In some disclosed examples, the component may fail validation because hole plug(s) may be missing and/or incorrect color(s) of hole plugs is/are used (and thereby indicate(s) that incorrect sized hole plug(s) is/are used). Advantageously, the component may be modified and/or otherwise reworked to become validated prior to undergoing subsequent manufacturing processes.

Advantageously, in some disclosed examples, execution of image-processing machine-learning models and implementation of natural language processing techniques eliminate and/or otherwise reduce manual validations of prior hole plug related manufacturing processes. Advantageously, in some disclosed examples, execution of image-processing machine-learning models and implementation of natural language processing techniques improve manufacturing efficiency (e.g., achieve reduced man hours to manufacture components) and quality of verification and/or validation processes associated with hole plugs in mechanical components.

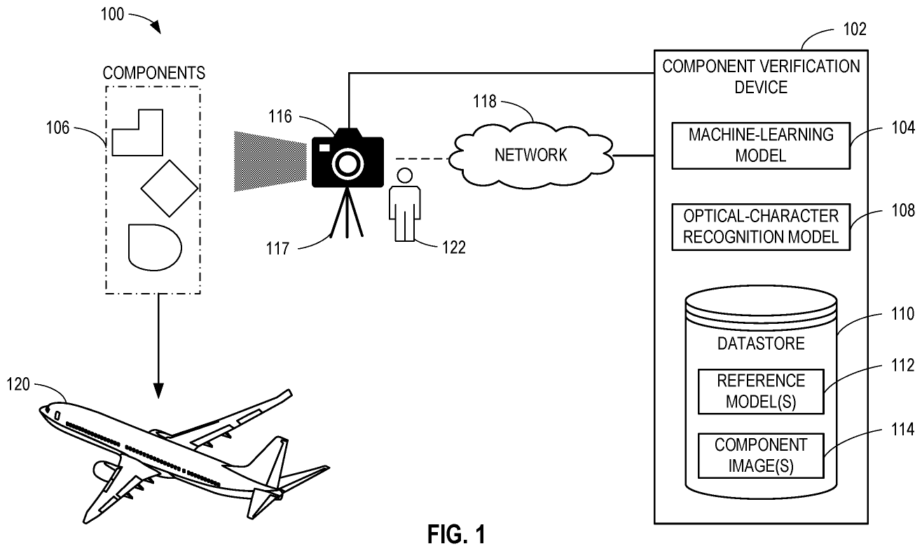

FIG. 1 is an illustration of an example component verification system 100, which includes an example component verification device 102 that at least one of executes or instantiates a machine-learning model 104 to validate hole plug placement for example aircraft components 106. In the illustrated example, the component verification device 102 includes an example optical-character recognition (OCR) model 108, an example datastore 110, which includes example reference model(s) 112 and example component image(s) 114. Further depicted in the illustrated example of FIG. 1 is an example camera 116, and example network 118, and an example aircraft 120.

In some examples, one(s) of the components 106 is/are manufactured in accordance based on Full Size Determinant Assembly (FSDA) principles. For example, a first one of the components 106 can be an aircraft doubler structure that includes full-sized holes that are drilled without the aid or use of a fixture. In some examples, after verification by the component verification system 100, the aircraft doubler structure can be integrated into an aircraft subassembly and/or, more generally, into the aircraft 120. The aircraft 120 of the illustrated is a commercial aircraft. Alternatively, the aircraft 120 may be any other type of vehicle, such as a marine-based vehicle (e.g., a buoy, a boat, a ship, a tanker, etc.), a land-based vehicle (e.g., an automobile, a bus, a train car, etc.), a space vehicle (e.g., a capsule, a satellite, a spacecraft, etc.), etc.

In some examples, the component verification system 100 can verify whether one(s) of the components 106 satisfy requirements or specifications corresponding to the one(s) of the components 106. For example, the component verification system 100 can determine whether one(s) of the components 106 is/are constructed, manufactured, and/or otherwise built in accordance with the requirements or specifications. In some examples, the requirements, specifications, etc., can include blueprints, dimensions, engineering drawings, models (e.g., computer-aided design (CAD) models, 2-dimensional (2-D) models, three-dimensional (3-D) models, etc.), qualifications, ratings, schematics, standards, etc. For example, the requirements, specifications, etc., can include a reference model (e.g., a reference computer-based model) of one of the components 106. In some examples, the reference model can include identifications of locations on the one of the components 106 at which full-sized holes (rather than initial or pilot holes) are to be drilled. In some examples, the reference model can include an identification of a type of hole plug, a size of the hole plug, and/or a color of the hole plug to be inserted into the full-sized holes. In some examples, the identification, size, and/or color of hole plug corresponds to dimensions of the full-sized hole in which the hole plug is to be inserted.

By way of example, an example operator 122 builds a first one of the components 106. The first one of the components 106 can be a doubler (e.g., an aircraft doubler) that is to be integrated into the aircraft 120. Alternatively, the first one of the components 106 may be any other type of aircraft component, such as an aileron, a flap, a wing or wing portion, etc. For example, the doubler can be a sheet-metal component (or a composite component) used to strengthen and stiffen a repair in a sheet-metal structure (or a composite component), such as a wing of the aircraft 120, a fuselage of the aircraft 120, a vertical stabilizer of the aircraft 120, etc. The operator 122 can drill a plurality of full-sized holes of various diameters into the first one of the components 106 based on FSDA principles. In some examples, the operator 122 can be a human operator or a machine-based operator (e.g., a robot, a collaborative robot, an autonomous robot, etc.). After drilling the plurality of full-sized holes, the operator 122 inserts a hole plug into respective ones of the full-sized holes. In some examples, the hole plug can be of a particular type (e.g., a soft or pliable hole plug, a liquid foam hole plug, etc.), size, and/or color that corresponds to a diameter of the hole in which the hole plug is to be inserted. After insertion of the hole plugs, the camera 116 can capture an image, a video, etc., of the first one of the components 106. In some examples, the camera 116 is part of a machine-based operator, such as by being coupled to and/or included in the machine-based operator (e.g., a robot with one or more cameras).

In some examples, the camera 116 outputs the image, the video, etc., to the component verification device 102. For example, the component verification device 102 can store the image, the video, etc., from the camera 116 in the datastore 110 as the component image(s) 114. In the illustrated example, the camera 116 can output the image, the video, etc., to the component verification device 102 via the network 118. Alternatively, the camera 116 may output the image, the video, etc., to the component verification device 102 without utilizing the network 118. For example, the camera 116 can be in direct wired and/or wireless communication with the component verification device 102 without an intervening gateway, router, or other network interface device. Alternatively, the camera 116 may be any other type of optical sensor, such as a light detection and ranging (LIDAR) sensor, a laser, etc. The camera 116 of the illustrated example is coupled to a tripod 117. Alternatively, the camera 116 may not be coupled to a tripod. Additionally or alternatively, the camera 116 may be configured and/or set to capture images of the components 106 using any other support structure.

The component verification device 102 of the illustrated example is a server. Alternatively, the component verification device 102 may be a personal computer, a workstation, a self-learning machine (e.g., a neural network), a mobile device (e.g., a cell phone, a smart phone, a tablet such as an iPad™), a headset (e.g., an augmented reality (AR) headset, a virtual reality (VR) headset, etc.) or other wearable device, or any other type of computing and/or electronic device.

In some examples, the component verification device 102 is coupled to and/or configured to receive images from the camera 116. For example, the component verification device 102 can be a personal computer (e.g., a desktop computer, a laptop computer, etc.), a mobile device, etc., associated with the operator 122 and/or, more generally, the camera 116.

In some examples, the component verification device 102 can be a server or any other type of electronic and/or computing device that is not co-located in the same geographical area as the components 106. In some such examples, the component verification device 102 can be a server (or any other type of electronic and/or computing device) of a central facility, a cloud-based server, a virtualized server instantiated by a cloud services provider, etc. In some examples, the component verification device 102 can be a server or any other type of electronic and/or computing device that is co-located with and/or proximate to the components 106. For example, the component verification device 102 can be a server (or any other type of electronic and/or computing device) managed by a supplier of the components 106, and the server can be operational on the same or nearby premises to where the components 106 are manufactured.

The network 118 of the illustrated example of FIG. 1 is the Internet. However, the network 118 may be implemented using any suitable wired and/or wireless network(s) including, for example, one or more data buses, one or more Local Area Networks (LANs), one or more wireless LANs, one or more cellular networks, one or more private networks, one or more public networks, etc., and/or any combination(s) thereof.

In the illustrated example of FIG. 1, the component verification device 102 can execute and/or instantiate one or more models using the image of the first one of the components 106 as model input(s) to the one or more models. For example, the component verification device 102 can execute the OCR model 108 using the image as OCR model input(s) to generate OCR model output(s), which can include identifications of alphanumeric characters on the first one of the components 106 in the image. For example, the first one of the components 106 can be labeled, marked, etc., with one or more alphabetic letters, numbers, etc., and/or any combination(s) thereof, which can be used to identify the first one of the components 106, a manufacturing stage of the first one of the components 106, and/or a contract or work order (e.g., a manufacturing work order) associated with the first one of the components 106. Additionally or alternatively, the first one of the components 106 may be marked, labeled, etc., with one or more symbols or indicia, such as a bar code, a quick response (QR) code, etc., and/or any combination(s) thereof. In some examples, the OCR model 108 can detect the labels/markings on the first one of the components 106 in the image and identify the first one of the components 106 based on the detected labels/markings. For example, the OCR model 108 can detect that the first one of the components 106 is marked with the text “DOUBLER” and identify the first one of the components 106 as a doubler based on the detected text.

In some examples, the OCR model 108, and/or, more generally, the component verification device 102, can identify a first reference model of the reference model(s) 112 that corresponds to the first one of the components 106. For example, after the OCR model 108 identifies that the first one of the components 106 is an aircraft doubler, the OCR model 108 can identify one of the reference model(s) 112 that corresponds to the identified aircraft doubler. For example, the one of the reference model(s) 112 can be a CAD model (or any other type of computer-based model) of the aircraft doubler. In some examples, the one of the reference model(s) 112 can include hole plug data or information, such as a number of hole plugs to be inserted into the aircraft doubler, locations of the hole plugs in the aircraft doubler, sizes (e.g., dimensions, diameters, lengths, etc.) of the hole plugs, colors of the hole plugs, etc.

In some examples, the component verification device 102 executes the machine-learning model 104 to identify hole plugs in the image of the first one of the components 106. For example, the machine-learning model 104 can be used to implement machine-vision (e.g., computer-vision) technique(s) to identify a number of hole plugs in the first one of the components 106, locations of the hole plugs, sizes (e.g., diameters, lengths, etc.) of the hole plugs, colors of the hole plugs, dimensions of the hole plugs (e.g., dimensions that correspond to the colors of the hole plugs), etc.

In some examples, the component verification device 102 can compare whether there is/are differences with respect to hole plugs based on the one of the reference model(s) 112 and the image of the first one of the components 106. For example, the component verification device 102 can compare a first number of hole plugs in the image of the first one of the components 106 to a second number of hole plugs in the one of the reference model(s) 112. In some examples, the component verification device 102 can determine that there are differences between the image of the first one of the components 106 and the reference model corresponding to the first one of the components 106 based on the first number of hole plugs being different than the second number of hole plugs. In some examples, the component verification device 102 can determine that there are no differences with respect to a number of hole plugs when the first number is the same as the second number.

In some examples, the component verification device 102 can compare first colors of respective ones of the first hole plugs in the image of the first one of the components 106 to second colors of respective ones of the second hole plugs in the one of the reference model(s) 112. In some examples, the component verification device 102 can determine that there are differences between the image of the first one of the components 106 and the reference model corresponding to the first one of the components 106 based on one(s) of the first colors being different than one(s) of the second colors. In some examples, the component verification device 102 can determine that there are no differences with respect to hole plug colors when the first colors are the same and/or otherwise match the second colors.

In some examples, the component verification device 102 can verify that the first one of the components 106 is manufactured to meet and/or satisfy requirements, specifications, etc., associated with the first one of the components 106. For example, the component verification device 102 can verify that the first one of the components 106 meets the requirements, specifications, etc., based on a determination that there are no differences in at least one of the number of hole plugs or hole plug colors in the first one of the components 106. In some examples, the component verification device 102 can cause the first one of the components 106 to undergo a subsequent manufacturing operation, such as by being integrated and/or coupled to the aircraft 120, based on the verification.

In some examples, the component verification device 102 cannot verify that the first one of the components 106 meets the requirements, specifications, etc., based on a determination that there is/are difference(s) in at least one of the number of hole plugs or hole plug colors in the first one of the components 106. In some examples, the component verification device 102 can cause the first one of the components 106 to undergo modification, such as by replacing incorrectly used hole plugs with the correct ones (per the one of the reference model(s) 112) and/or inserting hole plugs in holes that were erroneously not plugged, based on the first one of the components 106 not being verified, validated, approved, etc.

In some examples, the component verification device 102 can execute, instantiate, and/or host a quick-run tool (e.g., an automation tool, a software tool, an automation tool plug-in, etc.) that works and/or executes along with 3D CAD models of the components 106 to generate and/or output details of the 3D CAD models. For example, the component verification device 102 can execute the quick-run tool to output 3D CAD model details such as coordinate locations of plugs of the components 106, colors of the plugs of the components 106, etc., that can be provided to the machine-learning model 104 as input(s) (e.g., model input(s)).

Advantageously, examples disclosed herein utilize artificial intelligence (AI) to eliminate and/or otherwise reduce manual validations of hole plug related manufacturing processes associated with the components 106. Advantageously, examples disclosed herein utilize AI to improve manufacturing efficiency by achieving reduction in the number of man hours needed to manufacture the components 106). Advantageously, examples disclosed herein utilize AI to improve the quality of verification and/or validation processes associated with hole plugs in the components 106.

AI, including machine learning (ML), deep learning (DL), and/or other artificial machine-driven logic (e.g., machine and/or computer vision, image processing, natural language processing, etc.), enables machines (e.g., computers, logic circuits, etc.) to use a model to process input data to generate an output based on patterns and/or associations previously learned by the model via a training process. For instance, the machine-learning model 104 can be trained with data to recognize patterns and/or associations and follow such patterns and/or associations when processing input data such that other input(s) result in output(s) consistent with the recognized patterns and/or associations.

Many different types of machine-learning models and/or machine-learning architectures exist. In some examples, the component verification device 102 generates the machine-learning model 104 as a neural network model. Using a neural network model enables the component verification device 102 to execute an AI/ML workload. In general, machine-learning models/architectures that are suitable to use in the example approaches disclosed herein include recurrent neural networks. However, other types of machine learning models could additionally or alternatively be used such as supervised learning ANN models, clustering models, classification models, etc., and/or a combination thereof. Example supervised learning ANN models may include two-layer (2-layer) radial basis neural networks (RBN), learning vector quantization (LVQ) classification neural networks, etc. Example clustering models may include k-means clustering, hierarchical clustering, mean shift clustering, density-based clustering, etc. Example classification models may include logistic regression, support-vector machine or network, Naive Bayes, etc. In some examples, the component verification device 102 may compile and/or otherwise generate the machine-learning model 104 as a lightweight machine-learning model.

In general, implementing an AI/ML system involves two phases, a learning/training phase and an inference phase. In the learning/training phase, a training algorithm is used to train the machine-learning model 104 to operate in accordance with patterns and/or associations based on, for example, training data. In general, the machine-learning model 104 include(s) internal parameters that guide how input data is transformed into output data, such as through a series of nodes and connections within the machine-learning model 104 to transform input data into output data. Additionally, hyperparameters are used as part of the training process to control how the learning is performed (e.g., a learning rate, a number of layers to be used in the machine learning model, etc.). Hyperparameters are defined to be training parameters that are determined prior to initiating the training process.

Different types of training may be performed based on the type of AI/ML model and/or the expected output. For example, the component verification device 102 may invoke supervised training to use inputs and corresponding expected (e.g., labeled) outputs to select parameters (e.g., by iterating over combinations of select parameters) for the machine-learning model 104 that reduces model error. As used herein, “labeling” refers to an expected output of the machine learning model (e.g., a classification, an expected output value, etc.). Alternatively, the component verification device 102 may invoke unsupervised training (e.g., used in deep learning, a subset of machine learning, etc.) that involves inferring patterns from inputs to select parameters for the machine-learning model 104 (e.g., without the benefit of expected (e.g., labeled) outputs).

In some examples, the component verification device 102 trains the machine-learning model 104 using unsupervised clustering of operating observables. For example, the operating observables may annotations of the component image(s) that identify a location of a hole plug in a component, a size of the hole plug, a color of the hole plug, etc. However, the component verification device 102 may additionally or alternatively use any other training algorithm such as stochastic gradient descent, Simulated Annealing, Particle Swarm Optimization, Evolution Algorithms, Genetic Algorithms, Nonlinear Conjugate Gradient, etc.

In some examples, the component verification device 102 may train the machine-learning model 104 until the level of error is no longer reducing. In some examples, the component verification device 102 may train the machine-learning model 104 locally on the component verification device 102 and/or remotely at an external computing system (e.g., a server, a physical and/or virtual machine implemented by a cloud services provider, etc.) communicatively coupled to the component verification device 102. In some examples, the component verification device 102 trains the machine-learning model 104 using hyperparameters that control how the learning is performed (e.g., a learning rate, a number of layers to be used in the machine learning model, etc.). In some examples, the component verification device 102 may use hyperparameters that control model performance and training speed such as the learning rate and regularization parameter(s). The component verification device 102 may select such hyperparameters by, for example, trial and error to reach an optimal model performance. In some examples, the component verification device 102 utilizes Bayesian hyperparameter optimization to determine an optimal and/or otherwise improved or more efficient network architecture to avoid model overfitting and improve the overall applicability of the machine-learning model 104. Alternatively, the component verification device 102 may use any other type of optimization. In some examples, the component verification device 102 may perform re-training. The component verification device 102 may execute such re-training in response to override(s) by a user of the component verification device 102, a receipt of new training data, etc.

In some examples, the component verification device 102 facilitates the training of the machine-learning model 104 using training data. In some examples, the component verification device 102 utilizes training data that originates from locally generated data, such as the reference model(s) 112, the component image(s) 114, annotations of the component image(s) 114, etc. In some examples, the component verification device 102 utilizes training data that originates from externally generated data, such as one(s) of the component image(s) 114 obtained from the camera 116 or from different camera(s) obtained via the network 118. In some examples where supervised training is used, the component verification device 102 may label the training data (e.g., label training data or portion(s) thereof as including particular types, colors, and/or sizes of hole plugs). Labeling is applied to the training data by a user manually or by an automated data pre-processing system. In some examples, the component verification device 102 may pre-process the training data using, for example, an interface (e.g., a network interface, network interface circuitry, a data extraction interface, data extraction circuitry, etc.) to extract alphanumeric characters, codes, labels, etc., and/or identify the components 106 and/or one(s) of the reference model(s) 112 that correspond to the components 106. In some examples, the component verification device 102 sub-divides the training data into a first portion of data for training the machine-learning model 104, and a second portion of data for validating the machine-learning model 104.

Once training is complete, the component verification device 102 may deploy the machine-learning model 104 for use as an executable construct that processes an input and provides an output based on the network of nodes and connections defined in the machine-learning model 104. The component verification device 102 may store the machine-learning model 104 in the datastore 110 and/or, more generally, in the component verification device 102. In some examples, the component verification device 102 may transmit (or cause transmission of) the machine-learning model 104 to external computing systems, such as computing systems in communication with cameras such as the camera 116 of the illustrated example. In some such examples, in response to transmitting the machine-learning model 104 to the external computing systems, the external computing systems may execute the machine-learning model 104 to execute AI/ML workloads with at least one of improved efficiency or performance.

Once trained, the deployed machine-learning model 104 may be operated in an inference phase to process data. In the inference phase, data to be analyzed (e.g., live data) is input to the machine-learning model 104, and the machine-learning model 104 executes to create output(s) (e.g., model output(s), machine-learning output(s), AI/ML output(s), etc.). This inference phase can be thought of as the AI “thinking” to generate the output(s) based on what it learned from the training (e.g., by executing the machine-learning model 104 to apply the learned patterns and/or associations to the live data). In some examples, input data undergoes pre-processing before being used as input(s) (e.g., model input(s), machine-learning input(s), AI/ML input(s), etc.) to the machine-learning model 104. Moreover, in some examples, the output data may undergo post-processing after it is generated by the machine-learning model 104 to transform the output(s) into a useful result (e.g., a display of data, a detection and/or identification of a hole plug, a detection and/or identification of a size and/or color of the hole plug, etc.).

In some examples, output(s) of the deployed machine-learning model 104 may be captured and provided as feedback. By analyzing the feedback, an accuracy of the deployed machine-learning model 104 can be determined. If the feedback indicates that the accuracy of the deployed machine-learning model 104 is less than a threshold (e.g., an accuracy threshold) or other criterion, training of an updated version of the machine-learning model 104 can be triggered using the feedback and an updated training data set, hyperparameters, etc., to generate an updated, deployed version of the machine-learning model 104.

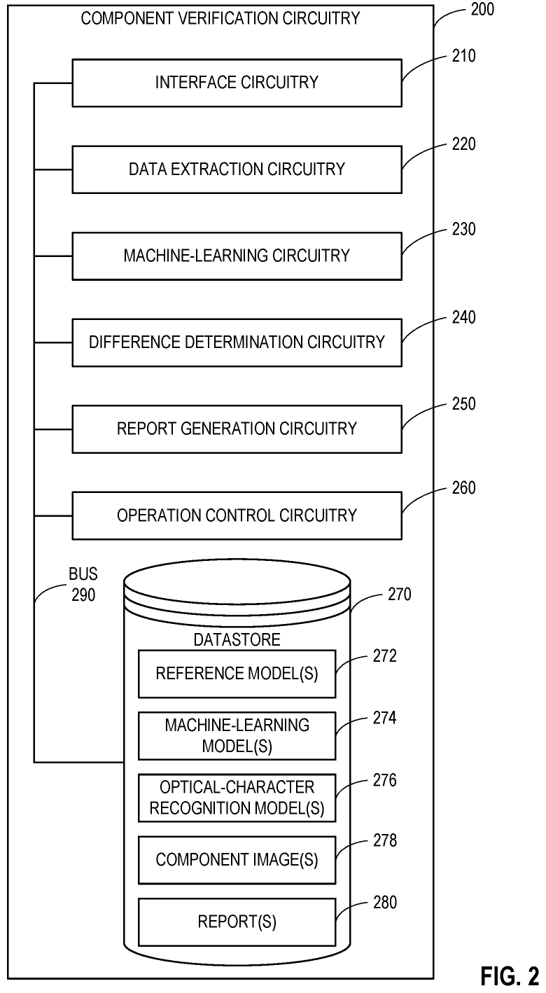

FIG. 2 is a block diagram of component verification circuitry 200 to validate hole plug placement for mechanical components, such as aircraft components for the aircraft 120 of FIG. 1. In some examples, the component verification device 102 of FIG. 1 can be implemented by the component verification circuitry 200 of FIG. 2. The component verification circuitry 200 of FIG. 2 may be instantiated (e.g., creating an instance of, bring into being for any length of time, materialize, implement, etc.) by processor circuitry such as a central processing unit executing instructions. Additionally or alternatively, the component verification circuitry 200 of FIG. 2 may be instantiated (e.g., creating an instance of, bring into being for any length of time, materialize, implement, etc.) by an Applicant Specific Integration Circuit (ASIC) or a Field Programmable Gate Array (FPGA) structured to perform operations corresponding to the instructions. It should be understood that some or all of the component verification circuitry 200 of FIG. 2 may, thus, be instantiated at the same or different times. Some or all of the component verification circuitry 200 may be instantiated, for example, in one or more threads executing concurrently on hardware and/or in series on hardware. Moreover, in some examples, some or all of the component verification circuitry 200 of FIG. 2 may be implemented by microprocessor circuitry executing instructions to implement one or more virtual machines and/or containers.

The component verification circuitry 200 of the illustrated example of FIG. 2 includes example interface circuitry 210, example data extraction circuitry 220, example machine-learning circuitry 230, example difference determination circuitry 240, example report generation circuitry 250, example operation control circuitry 260, an example datastore 270, and an example bus 290. The datastore 270 of the illustrated example of FIG. 2 includes example reference model(s) 272, example machine-learning model(s) 274, example optical-character recognition (OCR) model(s) 276, example component image(s) 278, and example report(s) 280. In some examples, the machine-learning model 104 of FIG. 1 can be implemented by one(s) of the machine-learning model(s) 274 of FIG. 2. In some examples, the OCR model 108 of FIG. 1 can be implemented by one(s) of the OCR model(s) 276 of FIG. 2. In some examples, the datastore 110 of FIG. 1 can be implemented by the datastore 270 of FIG. 2. In some examples, the component image(s) 114 of FIG. 1 can be implemented by the component image(s) 278 of FIG. 2. In some examples, the reference model(s) 112 of FIG. 1 can be implemented by the reference model(s) 272 of FIG. 2.

In the illustrated example of FIG. 2, the interface circuitry 210, the data extraction circuitry 220, the machine-learning circuitry 230, the difference determination circuitry 240, the report generation circuitry 250, the operation control circuitry 260, and the datastore 270 are in communication with one(s) of each other via the bus 290. For example, the bus 290 can be implemented by at least one of an Inter-Integrated Circuit (I2C) bus, a Serial Peripheral Interface (SPI) bus, a Peripheral Component Interconnect (PCI) bus, or a Peripheral Component Interconnect Express (PCIe or PCIE) bus. Additionally or alternatively, the bus 290 can be implemented by any other type of computing or electrical bus.

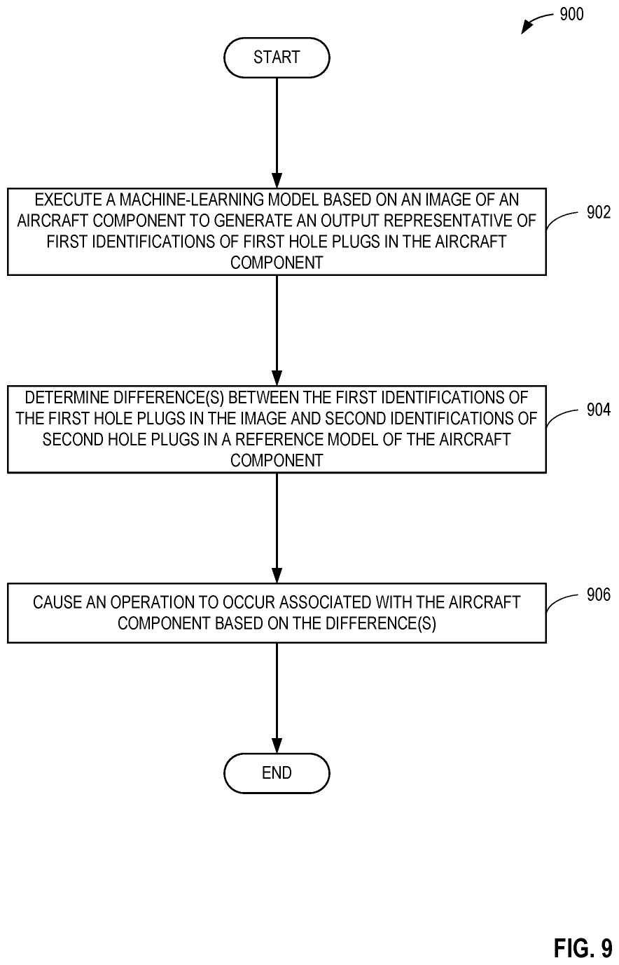

In the illustrated example of FIG. 2, the component verification circuitry 200 includes the interface circuitry 210 to receive and/or transmit data. In some examples, the interface circuitry 210 is instantiated by processor circuitry executing interface instructions and/or configured to perform operations such as those represented by one(s) of the flowcharts of FIGS. 9-12.

In some examples, the interface circuitry 210 can receive and/or obtain data, such as an image, a video, etc., from the camera 116 of FIG. 1. For example, the interface circuitry 210 can receive the image from a network, such as the network 118 of FIG. 1, and/or from the camera 116 (or any other electronic and/or computing device) via a direct wired or wireless connection. In some examples, the interface circuitry 210 can store the image in the datastore 270 as one of the component image(s) 278. In some examples, the interface circuitry 210 can receive data, information, etc., such as a model (e.g., the reference model(s) 272, the machine-learning model(s) 274, the OCR model(s) 276. For example, the interface circuitry 210 can obtain a trained and/or untrained model, such as a trained and/or untrained version of the machine-learning model(s) 274.

In some examples, the interface circuitry 210 can receive and/or obtain an indication that the machine-learning model(s) 274 generated an erroneous output. For example, the machine-learning circuitry 230 can execute and/or instantiate the machine-learning model(s) 274 based on an image of a first one of the components 106 of FIG. 1 to output a model output representative of identifying 10 hole plugs in the image. In some examples, the operator 122 of FIG. 1 can determine that the first one of the components 106 has 12 hole plugs. The operator 122 can generate an alert, an information technology (IT) help ticket, etc., that is representative of the discrepancy. In some examples, the interface circuitry 210 can obtain the alert, the IT help ticket, etc., (e.g., obtain via the network 118, obtain via a direct wired or wireless connection, etc.) and determine that the machine-learning model(s) 274 incorrectly identified the number of hole plugs in the first one of the components 106 based on the alert, the IT help ticket, etc. In some examples, the machine-learning circuitry 230 can retrain (or cause retraining of) the machine-learning model(s) 274 based on the alert, the IT help ticket, etc. In some examples, the operator 122 can include annotations of the image in the alert, the IT help ticket, etc. For example, the annotations can include identifications of each hole plug in the image, a size of the hole plug(s), a color of the hole plug(s), etc., and/or any combination(s) thereof. In some examples, the interface circuitry 210 can determine to monitor (or continue monitoring) for indication(s) to retrain the machine-learning model(s) 274.

In the illustrated example of FIG. 2, the component verification circuitry 200 includes the data extraction circuitry 220 to extract data and/or information from an image, such as the component image(s) 114 that may be obtained from the camera 116 and/or via the network 118. In some examples, the data extraction circuitry 220 is instantiated by processor circuitry executing data extraction instructions and/or configured to perform operations such as those represented by one(s) of the flowcharts of FIGS. 9-12.

In some examples, the data extraction circuitry 220 executes a model, such as the OCR model(s) 276, using an image of a first component of the components 106 of FIG. 1 as a model input to generate a model output representative of an identification of the first component in the image. For example, the data extraction circuitry 220 can execute and/or instantiate the OCR model(s) 276 based on the component image(s) 278 to extract data from the component image(s) 278, such as alphanumeric characters, codes, symbols, indicia, etc., and/or any combination(s) thereof that the first component may be marked and/or labeled with. In some examples, the data extraction circuitry 220 can execute the OCR model(s) 276 to generate an output representative of an identification of the first component based on the extracted data (e.g., the alphanumeric characters, codes, symbols, indicia, etc.) from the component image(s) 278.

In some examples, the data extraction circuitry 220 extracts data from a model, such as one(s) of the reference model(s) 272. For example, after an identification of the first component, which can be an aircraft doubler or any other aircraft component, the data extraction circuitry 220 can map the identification to a corresponding one of the reference model(s) 272. For example, the data extraction circuitry 220 can determine that the one of the reference model(s) 272 is a CAD model (or any other type of computer-based model) of the aircraft doubler based on a data association (e.g., a data association that may be stored in the datastore 270) of the CAD model and the aircraft doubler. In some examples, the data extraction circuitry 220 can extract data from the CAD model such as a number of hole plugs in a component represented by the CAD model. In some examples, the data extraction circuitry 220 can extract data from the CAD model such as a color (e.g., a detection and/or identification of a color) of respective ones of the hole plugs in the component represented by the CAD model.

In the illustrated example of FIG. 2, the component verification circuitry 200 includes the machine-learning circuitry 230 to execute and/or instantiate a machine-learning model, such as one(s) of the machine-learning model(s) 274, to generate output(s). In some examples, the machine-learning circuitry 230 is instantiated by processor circuitry executing machine-learning instructions and/or configured to perform operations such as those represented by one(s) of the flowcharts of FIGS. 9-12.

In some examples, the machine-learning circuitry 230 executes the machine-learning model(s) 274 to detect and/or identify one of the components 106 of FIG. 1 in the component image(s) 278. For example, before hole plugs are identified in a first one of the components 106, the machine-learning model(s) 274 can detect the first one of the components 106 in the component image(s) 278 to eliminate and/or otherwise reduce background noise in the component image(s) 278. For example, when the component image(s) 278 is/are taken, there may be other foreign objects, persons, etc., in close proximity to the first one of the components 106, which may hinder or impede hole plug detection. Advantageously, the machine-learning circuitry 230 can execute the machine-learning model(s) 274 to detect the first one of the components 106 prior to detecting hole plugs in the first one of the components 106.

In some examples, the machine-learning circuitry 230 executes the machine-learning model(s) 274 based on the component image(s) 278 of a component, such as a first component of the components 106 of FIG. 1. In some examples, the machine-learning circuitry 230 executes the machine-learning model(s) 274 to generate an output representative of first identifications of first hole plugs in the first component as depicted in the component image(s) 278. For example, the machine-learning circuitry 230 can determine a first number of hole plugs in the first component in the component image(s) 278 based on the first identifications of the first hole plugs. In some examples, the machine-learning circuitry 230 can identify colors of respective ones of the first hole plugs in the component image(s) 278. In some examples, the machine-learning circuitry 230 can determine a second number of hole plugs in the first component based on the reference model(s) 272. For example, the machine-learning circuitry 230 can obtain the reference model(s) 272 as input(s) to generate output(s), which can include second identifications of second hole plugs in the reference model(s) 272. Additionally or alternatively, the machine-learning circuitry 230 may determine the second identifications of second hole plugs in the reference model(s) 272 based on output(s) from an automation tool plug-in, which can generate the output(s) based on analyzing the reference model(s) 272 as input(s) to the automation tool plug-in.

In some examples, the machine-learning circuitry 230 can train an untrained machine-learning model to identify the components 106 and/or validate hole plug placement in vehicle components, such as components that may be integrated and/or otherwise associated with the aircraft 120 of FIG. 1. For example, the machine-learning circuitry 230 can train an untrained one of the machine-learning model(s) 274 using training data, which can include a plurality of images of aircraft components that include hole plugs and/or annotations, labels, etc., of the hole plugs. In some examples, the training data includes a plurality of images of the same component to train the machine-learning model(s) 274 to identify the component irrespective of the orientation (e.g., horizontal, vertical, top-down, bottom-up, etc., orientation) of the component in the image. In some examples, the training data includes a plurality of images of the same component with hole plugs to train the machine-learning model(s) 274 to identify the hole plugs irrespective of the orientation (e.g., horizontal, vertical, top-down, bottom-up, etc., orientation) of the hole plugs in the image. In some examples, the training data includes a plurality of images of the same component in different lighting conditions and/or environments to train the machine-learning model(s) 274 to identify a component and/or associated hole plugs irrespective of the lighting conditions (e.g., different levels of brightness).

In some examples, the machine-learning circuitry 230 can train the machine-learning model(s) 274 until a determination is reached that an accuracy of the machine-learning model(s) 274 achieves and/or is greater than a threshold (e.g., an accuracy threshold, a training threshold, etc.) and thereby satisfies the threshold. In some examples, after a determination that an accuracy threshold of a trained one of the machine-learning model(s) 274 is satisfied, the machine-learning circuitry 230 can store the trained one of the machine-learning model(s) 274 in the datastore 270 as one of the machine-learning model(s) 274. In some examples, the machine-learning circuitry 230 can identify the trained one of the machine-learning model(s) 274 as being available for deployment and/or use in inference operations. For example, the machine-learning circuitry 230 can deploy the trained one of the machine-learning model(s) 274 for inference operations locally (e.g., transmit the trained one of the machine-learning model(s) 274 to a computing and/or electronic system associated with the camera 116 of FIG. 1 via the network 118 of FIG. 1) and/or remotely (e.g., execute the trained one of the machine-learning model(s) 274 at a remote server or cloud-based service).

In some examples, the machine-learning circuitry 230 determines to retrain the machine-learning model(s) 274. For example, after a determination that a time period associated with model retraining has elapsed or been reached, the machine-learning circuitry 230 can retrain one(s) of the machine-learning model(s) 274 using training data. For example, the machine-learning circuitry 230 can retrain one(s) of the machine-learning model(s) 274 using one(s) of the component image(s) 278 in the datastore 270. In some examples, the machine-learning circuitry 230 can retrain one(s) of the machine-learning model(s) 274 based on annotation(s) of image(s) that caused erroneous model outputs. For example, the machine-learning circuitry 230 can execute the machine-learning model(s) 274 to generate an output based on a first component image of one of the components 106 of FIG. 1, and the output can be representative of a first number of hole plugs and/or first color(s) of the hole plugs. In some examples, the machine-learning circuitry 230 can retrain the machine-learning model(s) 274 based on one or more annotations of a second component image of the one of the components 106 of FIG. 1. For example, the one or more annotations can include identifications of hole plug locations, detections of a number of hole plugs, hole plug sizes, hole plug colors, etc., and/or any combination(s) thereof. Advantageously, the machine-learning circuitry 230 can retrain the machine-learning model(s) 274 using ground truth training data, such as component images including annotations of verified and/or validated data or information, to improve an accuracy of the machine-learning model(s) 274.

In the illustrated example of FIG. 2, the component verification circuitry 200 includes the difference determination circuitry 240 to determine difference(s) between an image of a component and a reference model that corresponds to the component. In some examples, the difference determination circuitry 240 is instantiated by processor circuitry executing difference determination instructions and/or configured to perform operations such as those represented by one(s) of the flowcharts of FIGS. 9-12.

In some examples, the difference determination circuitry 240 determines one or more differences between (1) first identifications of first hole plugs in one of the component image(s) 278 of a first component of the first components 106 and (2) second identifications of second hole plugs in one of the reference model(s) 272 of the first component. For example, the difference determination circuitry 240 can determine whether there is a difference between a first number of the first hole plugs and a second number of the second hole plugs. In some examples, the difference determination circuitry 240 can generate an output representative of a difference in the number of hole plugs between the one of the component image(s) 278 and the one of the reference model(s) 272 based on a determination that the first number of the first hole plugs and the second number of the second hole plugs is different.

In some examples, the difference determination circuitry 240 can determine whether there is a difference between first color(s) of respective ones of the first hole plugs and second color(s) of respective ones of the second hole plugs. In some examples, the difference determination circuitry 240 can generate an output representative of a difference in the first color(s) and the second color(s) based on a determination that one or more of the first color(s) are different from one or more of the second color(s).

In the illustrated example of FIG. 2, the component verification circuitry 200 includes the report generation circuitry 250 to generate a report, such as one of the report(s) 280, based on comparisons of the component image(s) 278 to corresponding one(s) of the reference model(s) 272. For example, the report generation circuitry 250 can determine whether there is/are differences between the component image(s) 278 and corresponding one(s) of the reference model(s) 272 based on the comparisons and indicate such on the report(s) 280. In some examples, the report generation circuitry 250 can generate a report that indicates that no differences are detected or that one or more differences are detected. For example, the report generation circuitry 250 can store the report in the datastore 270 as one of the report(s) 280. In some examples, the report generation circuitry 250 is instantiated by processor circuitry executing report generation instructions and/or configured to perform operations such as those represented by one(s) of the flowcharts of FIGS. 9-12.

In some examples, after a determination that there are no differences between the component image(s) 278 and corresponding one(s) of the reference model(s) 272, the report generation circuitry 250 can generate and/or store a data association of a successful verification and a component. For example, after a determination that a first one of the components 106 of FIG. 1 has a number of hole plugs and/or colors of hole plugs as indicated by a corresponding one of the reference model(s) 272, the report generation circuitry 250 can generate a data association of the first one of the components 106 and a successful verification. The data association can indicate that the first one of the components 106 is successfully verified based on corresponding requirements, specifications, etc., and that the first one of the components 106 is approved, verified, and/or validated to undergo subsequent manufacturing operations such as painting, shipment to a location, integration into the aircraft 120 of FIG. 1, etc.

In some examples, after a determination that there is at least one difference between the component image(s) 278 and corresponding one(s) of the reference model(s) 272, the report generation circuitry 250 can generate and/or store a data association of a failed or unsuccessful verification and a component. For example, after a determination that a first one of the components 106 of FIG. 1 has a different number of hole plugs and/or different colors of hole plugs are used than indicated by a corresponding one of the reference model(s) 272, the report generation circuitry 250 can generate a data association of the first one of the components 106 and a failed or unsuccessful verification. The data association can indicate that the first one of the components 106 failed verification and/or otherwise is unsuccessfully verified based on corresponding requirements, specifications, etc., and that the first one of the components 106 is not approved, verified, or validated to undergo subsequent manufacturing operations such as painting, shipment to a location, integration into the aircraft 120 of FIG. 1, etc.

In the illustrated example of FIG. 2, the component verification circuitry 200 includes the operation control circuitry 260 to cause an operation associated with a component, such as one of the components 106 of FIG. 1, to occur based on whether difference(s) is/are detected with respect to an image of the component and a reference model that corresponds to the component. In some examples, the operation control circuitry 260 is instantiated by processor circuitry executing operation control instructions and/or configured to perform operations such as those represented by one(s) of the flowcharts of FIGS. 9-12.

In some examples, the operation control circuitry 260 causes a component to be integrated into a vehicle, such as the aircraft 120 of FIG. 1. For example, after a determination that one of the report(s) 280 indicates that no differences between a component image and a reference model of one of the components 106 is identified, the operation control circuitry 260 can cause the one of the components 106 to undergo one or more manufacturing operations to facilitate its integration into the aircraft 120. For example, the operation control circuitry 260 can generate a command, a direction, an instruction, a work order, a work sequence, etc., to cause human and/or machine operators (e.g., a robot, a forklift, an autonomous machine of any kind, etc.) to carry out and/or perform one or more manufacturing operations on the component such as painting, shipment, affixing the component onto another component and/or the aircraft 120, etc., and/or any combination(s) thereof. In some examples, the operation control circuitry 260 can transmit the command, the direction, the instruction, the work order, the work sequence, etc., to the human and/or machine operators to cause the one or more manufacturing operations to be conducted. For example, the operation control circuitry 260 can transmit the work order to the robot (e.g., via one or more networks, via a direct wired and/or wireless connection, etc.) to cause the robot to paint the component. In some examples, the operation control circuitry 260 can transmit an alert, a notification, etc., to an electronic and/or computing device associated with the operator 122 of FIG. 1 to instruct the operator 122 to carry out the work order.

In some examples, the operation control circuitry 260 causes a component to be modified prior to integration into a vehicle, such as the aircraft 120 of FIG. 1. For example, after a determination that one of the report(s) 280 indicates that there is at least one difference (e.g., a hole plug is missing, a different color hole plug is used, etc.) between a component image and a reference model of one of the components 106 is identified, the operation control circuitry 260 can cause the one of the components 106 to be adjusted and/or modified prior to undergoing one or more manufacturing operations to facilitate its integration into the aircraft 120. For example, the operation control circuitry 260 can generate a command, a direction, an instruction, a work order, a work sequence, etc., to cause human and/or machine operators (e.g., a robot, a forklift, an autonomous machine of any kind, etc.) to carry out and/or perform one or more modifications on the component such as adding a previously missing hole plug, changing a size of a hole plug, changing a hole plug of a first color to a hole plug of a different color, etc., and/or any combination(s) thereof. In some examples, the operation control circuitry 260 can transmit the command, the direction, the instruction, the work order, the work sequence, etc., to the human and/or machine operators to cause the one or more adjustments, changes, modifications, etc., to be conducted. For example, the operation control circuitry 260 can transmit the work order to the robot (e.g., via one or more networks, via a direct wired and/or wireless connection, etc.) to cause the robot to add a hole plug to the component. In some examples, the operation control circuitry 260 can transmit an alert, a notification, etc., to an electronic and/or computing device associated with the operator 122 of FIG. 1 to instruct the operator 122 to carry out the work order to add the hole plug, change an aspect of the hole plug (e.g., a size and/or color), etc.

The component verification circuitry 200 includes the datastore 270 to record data and/or information such as the reference model(s) 272, the machine-learning model(s) 274, the OCR model(s) 276, the component image(s) 278, and the report(s) 280. The datastore 270 may be implemented by a volatile memory (e.g., a Synchronous Dynamic Random Access Memory (SDRAM), Dynamic Random Access Memory (DRAM), RAMBUS Dynamic Random Access Memory (RDRAM), etc.) and/or a non-volatile memory (e.g., flash memory). The datastore 270 may additionally or alternatively be implemented by one or more double data rate (DDR) memories, such as DDR, DDR2, DDR3, DDR4, DDR5, mobile DDR (mDDR), DDR SDRAM, etc. The datastore 270 may additionally or alternatively be implemented by one or more mass storage devices such as hard disk drive(s) (HDD(s)), compact disk (CD) drive(s), digital versatile disk (DVD) drive(s), solid-state disk (SSD) drive(s), Secure Digital (SD) card(s), CompactFlash (CF) card(s), etc. While in the illustrated example the datastore 270 is illustrated as a single datastore, the datastore 270 may be implemented by any number and/or type(s) of datastores. Furthermore, the data stored in the datastore 270 may be in any data format such as, for example, binary data, comma delimited data, a tab delimited data, structured query language (SQL) structures, etc.

In some examples, the datastore 270 can implement and/or include one or more databases. The term “database” as used herein means an organized body of related data, regardless of the manner in which the data or the organized body thereof is represented. For example, the organized body of related data may be in the form of one or more of a table, a map, a grid, a packet, a datagram, a frame, a file, an e-mail, a message, a document, a report, a list or in any other form.

In some examples, the reference model(s) 272 include one or more computer-based models of one or more respective components, such as two-dimensional (2D) computer-aided design (CAD) models, three-dimensional (3D) CAD models, etc. For example, the reference model(s) 272 can include a 3D wireframe model, a surface model, a solid model, a polygonal model, a rational B-spline model, a non-uniform rational basis spline (NURBS) model, etc., of a first one of the components 106 of FIG. 1 in any other of native or neutral file format.

In some examples, the machine-learning model(s) 274 include one or more AI/ML models to execute AI/ML workloads, such as image processing, object recognition, OCR, pattern classification, machine vision, etc. For example, the machine-learning model(s) 274 can be any type of deep learning model, such as a neural network (e.g., a convolution neural network, a recurrent neural network, a perceptron neural network, etc.). Additionally or alternatively, the machine-learning model(s) 274 may be a supervised learning ANN model, a clustering model, a classification model, etc., and/or any combination(s) thereof.

In some examples, the OCR model(s) 276 include one or more types of recognition models. For example, the OCR model(s) 276 can include a simple OCR engine, a deep learning character recognition model, an intelligent word recognition model, an intelligent character recognition model, an OCR model, an optical word recognition model, an optical mark recognition model, etc., and/or any combination(s) thereof.

In some examples, the component image(s) 278 include one or more images and/or videos of vehicle components, such as components associated with an aerial vehicle, a land vehicle, a marine vehicle, a space vehicle, etc. For example, the component image(s) 278 can be implemented by digital data in any type of image and/or video format, such as Animated Portable Network Graphics (APNG) format, Graphics Interchange Format (GIF), Joint Photographic Expert Group (JPEG) format, Portable Network Graphics (PNG) format, AV1 Image File Format (AVIF), Scalable Vector Graphics (SVG) format, Web Picture (WebP) format, etc. Alternatively, the component image(s) 278 may be implemented by a Bitmap File (BMP), a Tagged Image File Format (TIFF), etc.

In some examples, the report(s) 280 include one or more reports that are generated based on comparisons of images of components and reference models corresponding to the components. In some examples, the report(s) 280 can be implemented by any organized body or data structure of related data. For example, the report(s) 280 can be in the form of one or more of a table, a grid, a packet, a datagram, a frame, a file, an e-mail, a message, a document, a spreadsheet, a list (e.g., a checklist, a list of items, etc.), or in any other form.

While an example manner of implementing the component verification device 102 of FIG. 1 is illustrated in FIG. 2, one or more of the elements, processes, and/or devices illustrated in FIG. 2 may be combined, divided, re-arranged, omitted, eliminated, and/or implemented in any other way. Further, the interface circuitry 210, the data extraction circuitry 220, the machine-learning circuitry 230, the difference determination circuitry 240, the report generation circuitry 250, the operation control circuitry 260, and the datastore 270, and/or, more generally, the component verification device 102 of FIG. 1, may be implemented by hardware alone or by hardware in combination with software and/or firmware. Thus, for example, any of the interface circuitry 210, the data extraction circuitry 220, the machine-learning circuitry 230, the difference determination circuitry 240, the report generation circuitry 250, the operation control circuitry 260, and/or, more generally, the component verification device 102, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example component verification device 102 of FIG. 1 may include one or more elements, processes, and/or devices in addition to, or instead of, those illustrated in FIG. 2, and/or may include more than one of any or all of the illustrated elements, processes and devices.

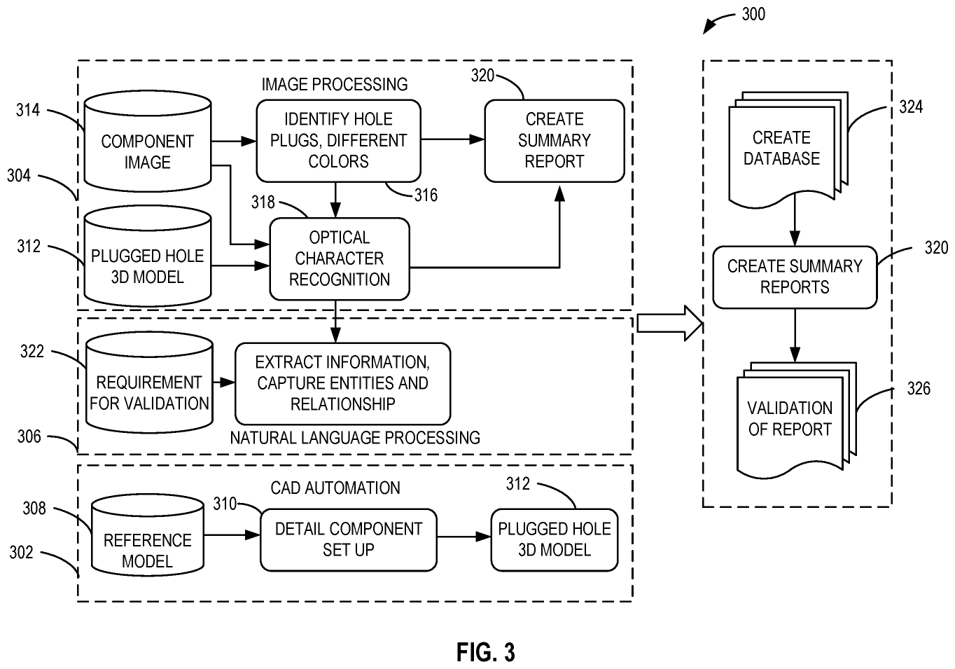

FIG. 3 is a block diagram of a first example workflow 300 to implement the example component verification system 100 of FIG. 1. The first workflow 300 of the illustrated example includes an example CAD automation workflow 302, an example image processing workflow 304, and an example natural language processing workflow 306. In some examples, the first workflow 300, portion(s) thereof, can be implemented by the component verification device 102 of FIG. 1. In some examples, the first workflow 300, portion(s) thereof, can be implemented by the component verification circuitry 200 of FIG. 2.

During the CAD automation workflow 302, the component verification circuitry 200 can output a model of a component (e.g., an aircraft component, a vehicle component, etc.) that includes hole details, such as coordinates of one or more hole plugs, a color of the one or more hole plugs, dimensions of the one or more hole plugs, etc. During the CAD automation workflow 302, the component verification circuitry 200 can obtain an example reference model 308. In some examples, the reference model 308 can be a computer-based model of one of the components 106 of FIG. 1. In some examples, the reference model 308 can be implemented by the reference model(s) 112 of FIG. 1 and/or the reference model(s) 272 of FIG. 2.

During the CAD automation workflow 302, the component verification circuitry 200 can execute and/or instantiate CAD automation operations 310, which can include simulating setting up various layers of the reference model 308, identifying details of setting up the component for manufacturing (e.g., identifying drill locations of one or more holes in the component), simulating running a tool on the component (e.g., simulate using a drill press on the drill locations), etc., to output an example plugged hole 3D model 312. For example, the plugged hole 3D model 312 can be a computer-based model of the component that includes one or more full-sized holes, one or more hole plugs to be inserted into the one or more full-sized holes, details of the one or more hole plugs such as a type, color, and/or size, etc.

During the image processing workflow 304, the component verification circuitry 200 can execute and/or instantiate machine-learning model(s) (e.g., the machine-learning model 104 of FIG. 1 and/or the machine-learning model(s) 274 of FIG. 2) to determine difference(s) in hole plug(s) in the plugged hole 3D model and an example component image 314. In some examples, the component image 314 can be an image of a component, such as one of the components 106 of FIG. 1. In some examples, the component image 314 can be implemented by the component image(s) 114 of FIG. 1 and/or the component image(s) 278 of FIG. 2.

During the image processing workflow 304, the component verification circuitry 200 can execute and/or instantiate the machine-learning model(s) using the component image 314 as model input(s) to generate model output(s), which include example hole plug identifications 316. For example, the hole plug identifications 316 can include an identification of a number of hole plugs in the component, colors of the respective hole plugs, etc. The component verification circuitry 200 can execute an example OCR model 318 on the component image 314 to extract symbol(s), text, etc., on the component in the component image 314, which can be used to identify the component in the component image 314. In some examples, the OCR model 318 can be implemented by the OCR model 108 of FIG. 1 and/or the OCR model(s) 276 of FIG. 2. After an identification of the component based on the extracted symbol(s), text, etc., the component verification circuitry 200 can determine that the component in the component image 314 corresponds to the plugged hole 3D model (e.g., the plugged hole 3D model is a computer-based model of the component in the component image 314). During the image processing workflow 304, the component verification circuitry 200 can compare the hole plug identifications 316 to hole plug identifications of the plugged hole 3D model to output an example summary report 320. In some examples, the summary report can be implemented by the report(s) 280 of FIG. 2.

During the natural language processing workflow 306, the component verification circuitry 200 can determine that the component in the component image 314 corresponds to an example requirement for validation 322. For example, the requirement for validation 322 can include one or more requirements, specifications, standards, etc., that define the manufacturing of the component in the component image 314. During the natural language processing workflow 306, the component verification circuitry 200 can extract information, capture entities and relationships, etc., from the requirement for validation 322 using one or more natural language processing techniques and/or models. Advantageously, the component verification circuitry 200 can determine whether the component in the component image 314 is manufactured in accordance with the requirement for validation 322.

During the first workflow 300, the component verification circuitry 200 can create and/or generate an example database 324, which can store one or more of the summary reports 320. In some examples, the database 324 can be implemented by the datastore 110 of FIG. 1 and/or the datastore 270 of FIG. 2. During the first workflow 300, the component verification circuitry 200 can execute validations 326 of the summary reports 320. For example, the component verification circuitry 200 can determine whether the summary reports 320 indicate that corresponding one(s) of the components 106 of FIG. 1 is/are built, manufactured, etc., in accordance with the requirement for validation 322.

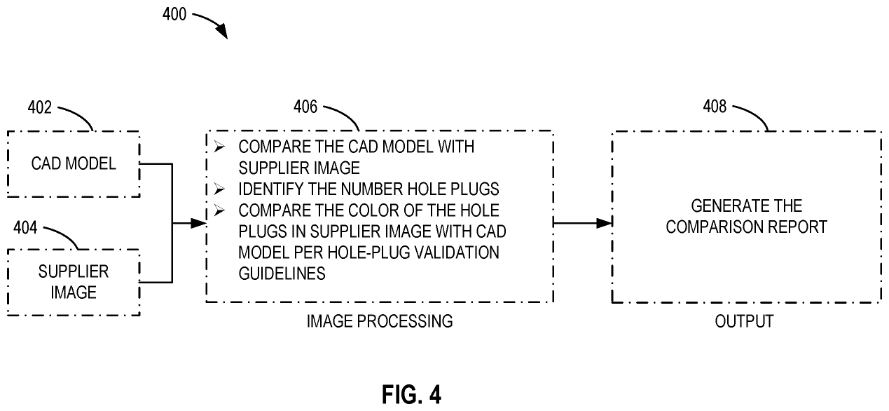

FIG. 4 is a block diagram of a second example workflow 400 to implement the example component verification system 100 of FIG. 1. In some examples, the second workflow 400, portion(s) thereof, can be implemented by the component verification device 102 of FIG. 1. In some examples, the second workflow 400, portion(s) thereof, can be implemented by the component verification circuitry 200 of FIG. 2.

During the second workflow 400, the component verification circuitry 200 can execute an example image processing workflow 406 based on an example CAD model 402 and an example supplier photo 404. For example, the CAD model 402 can be a reference model, such as the reference model(s) 112 of FIG. 1 and/or the reference model(s) 272 of FIG. 2, of a component, such as one of the components 106 of FIG. 1. In some examples, the supplier image 404 can be an image obtained, captured, and/or generated by a supplier, manufacturer, vendor, etc., of the component. For example, the supplier image 404 can be captured by the camera 116 of FIG. 1. In some examples, the supplier image 404 can be implemented by the component image(s) 114 of FIG. 1 and/or the component image(s) 278 of FIG. 2.

During the image processing workflow 406, the component verification circuitry 200 can execute and/or instantiate one or more operations such as comparing the CAD model 402 with the supplier image 404; identify a number of hole plugs in the supplier image 404; compare the color of the hole plugs in the supplier image 404 with the color of the hole plugs in the CAD model 402 per hole-plug validation guidelines, requirements, specifications, etc. After completion of the image processing workflow 406, the component verification circuitry 200 can generate an example output 408, which can include the comparison report based on identifying a number of hole plugs in the supplier image 404 and/or comparing colors of hole plugs in the supplier image 404 with respect to the CAD model 402. Advantageously, the component verification circuitry 200 can determine whether the component in the supplier image 404 is assembled, manufactured, produced, etc., in accordance with requirements, specifications, etc., associated with the component based on the comparison report.

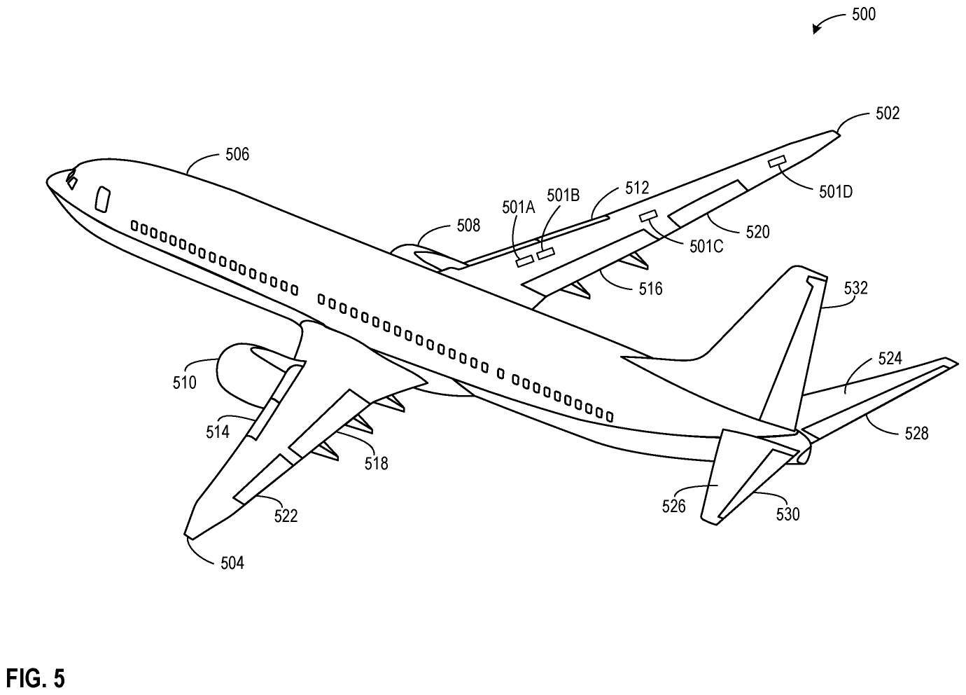

FIG. 5 is an illustration of an example aircraft 500 including example doublers 501A, 501B, 501C, 501D (collectively referred to as 501A-D). In some examples, the aircraft 120 of FIG. 1 can be implemented by the aircraft 500 of FIG. 5. In some examples, the component verification circuitry 200 of FIG. 2, the component verification device 102, and/or, more generally, the component verification system 100 of FIG. 1, can verify and/or validate whether components, such as the aircraft doublers 501A-D, are manufactured in accordance with associated requirements, specifications, etc. After a determination that a component is verified/validated, such as one of the doublers 501A-D, the component verification circuitry 200 can cause the component to be integrated into the aircraft 500.

The aircraft 500 of the illustrated example of FIG. 5 includes wings 502, 504 coupled to a fuselage 506. Engines 508, 510 are coupled to the wings 502, 504. Slats 512, 514, flaps 516, 518, and ailerons 520, 522 are operatively coupled to the wings 502, 504. Additional aircraft control surfaces of the aircraft 500 include horizontal stabilizers 524, 526 operatively coupled to elevators 528, 530 and a vertical stabilizer 532 coupled to the fuselage 506. Advantageously, the component verification circuitry 200 of FIG. 2, the component verification device 102, and/or, more generally, the component verification system 100 of FIG. 1, can verify/validate that the doublers 501A-D included the expected number and/or colors of hole plugs; cause one or more subsequent manufacturing operations to be carried out and/or performed on the doublers 501A-D such as painting the doublers 501A-D; and causing the doublers 501A-D to be coupled to the wing 502. For example, the component verification circuitry 200 of FIG. 2, the component verification device 102, and/or, more generally, the component verification system 100 of FIG. 1, can generate command(s) and/or instruct human and/or machine operators to manufacture the doublers 501A-D, paint the doublers 501A-D, and/or couple the doublers 501A-D to the wing 502.

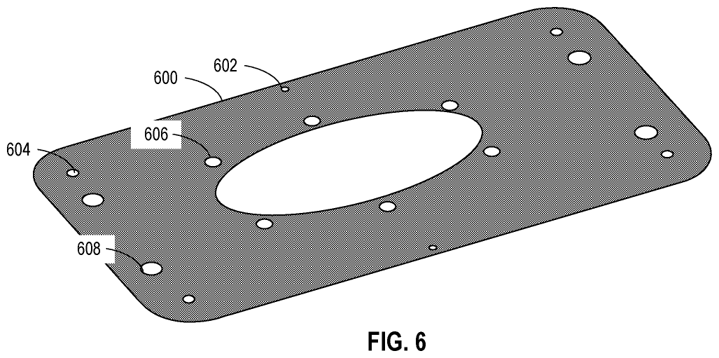

FIG. 6 is an illustration of an example doubler 600 without hole plugs. For example, FIG. 6 can be representative of a computer-based model of the doubler 600. In some examples, FIG. 6 can be representative of an image of a physical doubler. In some examples, the doubler 600 is a vehicle component, such as one of the example doublers 501A-D. The doubler 600 is a sheet-metal component (or a composite component) used to strengthen and stiffen a repair in a sheet-metal structure (or a composite component), such as one of the wings 502, 504 of FIG. 5, the fuselage 506 of FIG. 5, the vertical stabilizer 532 of FIG. 5, etc.

The doubler 600 of FIG. 6 can be manufactured based on FSDA principles or techniques. For example, the doubler 600 can be manufactured to include full-sized holes (rather than initial or pilot holes) 602, 604, 606, 608. The full-sized holes 602, 604, 606, 608 include a first example full-sized hole 602 of a first size (e.g., a first diameter), a second example full-sized hole 604 of a second size (e.g., a second diameter), a third example full-sized hole 606 of a third size (e.g., a third diameter), and a fourth example full-sized hole 608 of a fourth size (e.g., a fourth diameter). The first diameter of the first full-sized hole 602 of the illustrated example is smaller than the second diameter of the second full-sized hole 604. The second diameter of the second full-sized hole 604 is smaller than the third diameter of the third full-sized hole 606. The third diameter of the third full-sized hole 606 is smaller than the fourth diameter of the fourth full-sized hole 608.

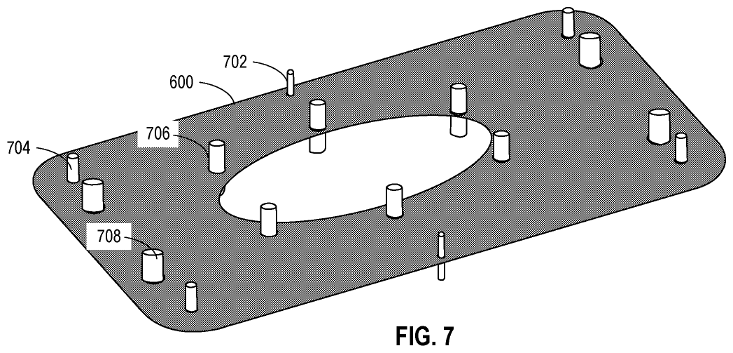

FIG. 7 is an illustration of the doubler 600 of FIG. 6 with hole plugs. For example, the first full-sized hole 602 of FIG. 6 is filled with a first example hole plug 702 of a first size and a first color. The second full-sized hole 604 of FIG. 6 is filled with a second example hole plug 704 of a second size and a second color. The third full-sized hole 606 of FIG. 6 is filled with a third example hole plug 706 of a third size and a third color. The fourth full-sized hole 608 of FIG. 6 is filled with a fourth example hole plug 708 of a fourth size and a fourth color. In the illustrated example, the first through fourth sizes are different from each other. In the illustrated example, the first through fourth colors are different from each other. For example, each hole plug color can indicate or represent a different size full-sized hole in the doubler 600.

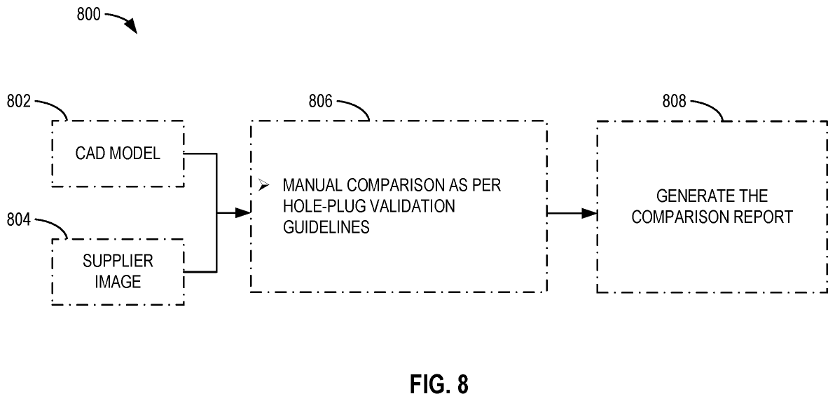

FIG. 8 is a block diagram of a third example workflow 800 to validate hole plug placement for an aircraft component. The third workflow 800 includes manual operations 806, which include manually (e.g., by one or more humans) comparing a CAD model 802 of a component and a supplier image 804 of the component per hole-plug validation guidelines. For example, a human user, operator, etc., can manually verify whether a component in the supplier image 804 has the correct number of hole plugs, the correct colors of hole plugs, etc. In some examples, the human user, operator, etc., consumes a substantial number of man hours, which is illustrated in the example of Table 1 below, and thereby substantially reduces manufacturing efficiency and increases lead times of producing mechanical components.

TABLE 1
Example Manual Operations to Validate Hole Plug Placement

| Part | Review | Image | Plug |
|---|---|---|---|
| Complexity | Hours | Quantity | Quantity |
| Simple | 1-2 | 2-6 | 1-50 |
| Medium | 2-4 | 6-19 | 50-200 |
| Complex | 4-10 | 20+ | 200+ |

As depicted above in the example of Table 1, the human user, operator, etc., may consume 1-2 man hours per component of simple complexity, 2-4 man hours per component of medium complexity, and 4-10 man hours per component of complex complexity. The human user, operator, etc., may spend the man hours analyzing multiple images (e.g., photos) with each image having a plurality of plugs (e.g., hole plugs). For example, a component of simple complexity (e.g., a simple component) can cause 1-2 man hours to be consumed to review 2-6 images and 1-50 plugs in the 2-6 images. By way of another example, a component of complex complexity can cause 4-10 man hours to be spent to review 20 or more images and 200 or more plugs in the 20 or more images. In some examples, review hours can extend to hundreds, thousands, or tens of thousands of hours when validating hole plug placement for a plurality of components to be integrated into a large and/or complex vehicle, such as the aircraft 500 of FIG. 5.

In some examples, the manual operations 806 may miss uncovered full-sized holes and may therefore cause subsequent issues during later manufacturing processes, testing, or real-world operation. After the manual operations 806, the human user, operator, etc., generates a comparison report 808, which can include detected differences between the CAD model 802 and the supplier image 804.

Advantageously, the component verification device 102 of FIG. 1, and/or, more generally, the component verification system 100 of FIG. 1, and/or the component verification circuitry 200 of FIG. 2, can substantially reduce the number of man hours to verify that a component is manufactured per the hole-plug validation guidelines. For example, the component verification circuitry 200 can identify a number of hole plugs and respective colors thereof in a component in the supplier image 804 and compare the number and respective colors to hole plugs in the CAD model 802 of the component with improved efficiency with respect to the manual operations 806. Advantageously, the component verification circuitry 200 can detect uncovered full-sized holes that may be missed during the manual operations 806 to eliminate and/or otherwise reduce subsequent issues that can arise during later manufacturing processes, testing, or real-world operation.

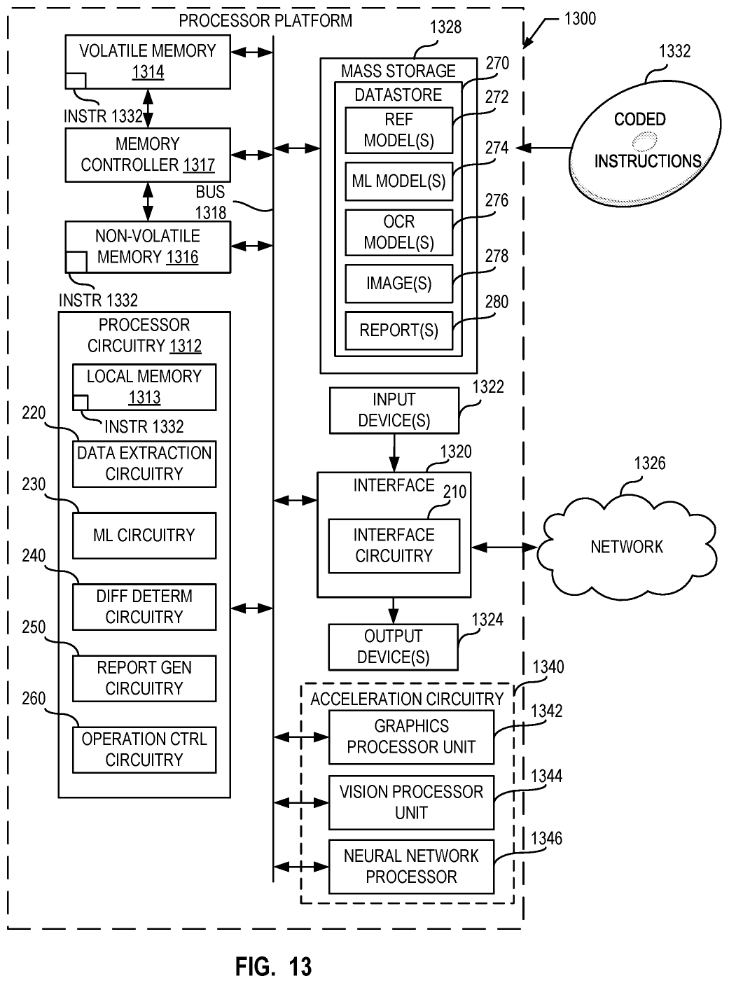

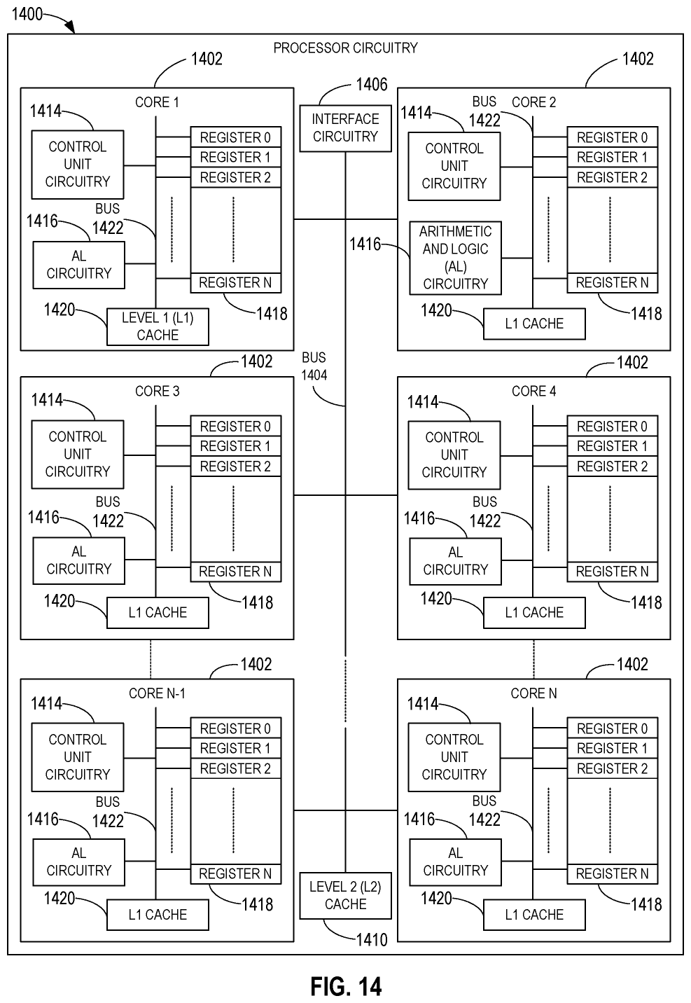

Flowcharts representative of example machine readable instructions, which may be executed to configure processor circuitry to implement the component verification circuitry 200 of FIG. 2, are shown in FIGS. 9-12. The machine readable instructions may be one or more executable programs or portion(s) of an executable program for execution by processor circuitry, such as the processor circuitry 1312 shown in the example processor platform 1300 discussed below in connection with FIG. 13 and/or the example processor circuitry discussed below in connection with FIGS. 14 and/or 15. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowcharts illustrated in FIGS. 9-12, many other methods of implementing the example component verification circuitry 200 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C #, Perl, Python, JavaScript, HyperText Markup Language (HTML), Structured Query Language (SQL), Swift, etc.

As mentioned above, the example operations of FIGS. 9-12 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium, non-transitory computer readable storage medium, non-transitory machine readable medium, and non-transitory machine readable storage medium are expressly defined to include any type of computer readable storage device and/or storage disk and to exclude propagating signals and to exclude transmission media. As used herein, the terms “computer readable storage device” and “machine readable storage device” are defined to include any physical (mechanical and/or electrical) structure to store information, but to exclude propagating signals and to exclude transmission media. Examples of computer readable storage devices and machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer readable instructions, machine readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 9 is a flowchart representative of example machine readable instructions and/or example operations 900 that may be executed and/or instantiated by processor circuitry to validate hole plug placement for an aircraft component. The example machine readable instructions and/or the example operations 900 of FIG. 9 begin at block 902, at which the component verification circuitry 200 executes a machine-learning model based on an image of an aircraft component to generate an output representative of first identifications of first hole plugs in the aircraft component. For example, the machine-learning circuitry 230 (FIG. 2) can execute and/or instantiate the machine-learning model(s) 274 based on the component image(s) 114 of a first component of the components 106 of FIG. 1, which can be the first aircraft doubler 501A of FIG. 5. For example, the component image(s) 114 can be captured and/or output from the camera 116 of FIG. 1. The machine-learning circuitry 230 can execute and/or instantiate the machine-learning model(s) 274 based on the component image(s) 114 as input(s) to generate output(s), which can include first identifications of first hole plugs in the first aircraft doubler 501A prior to the aircraft doubler 501A being integrated into the aircraft 500. For example, the first identifications can include a first total number of hole plugs (e.g., 5 hole plugs, 10 hole plugs, 20 hole plugs, etc.) and first respective colors (e.g., blue, red, yellow, black, etc.) of the hole plugs.

At block 904, the component verification circuitry 200 determines difference(s) between the first identifications of the first hole plugs in the image and second identifications of second hole plugs in a reference model of the aircraft component. For example, the difference determination circuitry 240 (FIG. 2) can determine whether there are one or more differences between the first identifications of the first hole plugs in the component image(s) 114 and second identifications of the hole plugs 702, 704, 706, 708 in the aircraft doubler 600 of FIGS. 6 and/or 7. For example, the data extraction circuitry 220 (FIG. 2) can determine that the first aircraft doubler 501A corresponds to one of the reference model(s) 272 (FIG. 2) based on extracted symbol(s), text, etc., on the first aircraft doubler 501A. In some examples, the data extraction circuitry 220 can determine that the one of the reference model(s) 272 that corresponds to the first aircraft doubler 501A includes (or depicts) second identifications of the hole plugs 702, 704, 706, 708 of FIG. 7. For example, the second identifications can include an identification that the one of the reference model(s) 272 of the aircraft doubler 600 includes two of the first hole plugs 702, four of the second hole plugs 704, six of the third hole plugs 706, and four of the fourth hole plugs 708. In some examples, the second identifications can include that (i) the two of the first hole plugs 702 have a first color (e.g., blue), (ii) the four of the second hole plugs 704 are a second color (e.g., red) that is different from the first color, (iii) the six of the third hole plugs 706 are a third color (e.g., yellow) that is different from the first and second colors, and (iv) the four of the fourth hole plugs 708 are a fourth color (e.g., black) that is different from the first through third colors. In some examples, the second identifications can include a determination that the one of the reference model(s) 272 of the aircraft doubler 600 has 16 total hole plugs.

In some examples, the difference determination circuitry 240 can determine that the first total number of hole plugs in the component image(s) 114 of the first aircraft doubler 501A is different from the second total number of hole plugs in the one of the reference model(s) 272 of the aircraft doubler 600 of FIGS. 6-7. In some examples, the difference determination circuitry 240 can determine that the first respective colors of hole plugs in the component image(s) 114 of the first aircraft doubler 501A is different from the second respective colors of hole plugs in the one of the reference model(s) 272 of the aircraft doubler 600 of FIGS. 6-7.

At block 906, the component verification circuitry 200 causes an operation to occur associated with the aircraft component based on the difference(s). For example, after a determination that the first aircraft doubler 501A has an unplugged full-sized hole, the operation control circuitry 260 (FIG. 2) can generate a work order to cause the operator 122 of FIG. 1 to fill the unplugged full-sized hole with a corresponding hole plug. For example, the data extraction circuitry 220 can determine that the unplugged full-sized hole in the component image(s) 114 corresponds to a hole plug having a particular size and/or color in the one of the reference model(s) 272. In some examples, the operation control circuitry 260 can cause the operator 122 to retrieve and/or insert the hole plug having the identified size and/or color in the first aircraft doubler 501A to facilitate verification and/or validation of the first aircraft doubler 501A for subsequent manufacturing operation(s).

In some examples, after a determination that the first aircraft doubler 501A has an incorrectly utilized color hole plug, the operation control circuitry 260 can generate a work order to cause the operator 122 of FIG. 1 to replace the incorrectly utilized color hole plug with the correct color hole plug. For example, the data extraction circuitry 220 can determine that the incorrectly utilized hole plug in the component image(s) 114 is blue while the corresponding hole plug in the one of the reference model(s) 272 is red. In some examples, the operation control circuitry 260 can cause the operator 122 to retrieve a red hole plug and/or replace the blue color hole plug with the red hole plug in the first aircraft doubler 501A to facilitate verification and/or validation of the first aircraft doubler 501A for subsequent manufacturing operation(s). After causing an operation to occur associated with the aircraft component based on the difference(s) at block 906, the example machine-readable instructions and/or the example operations 900 of FIG. 9 conclude.

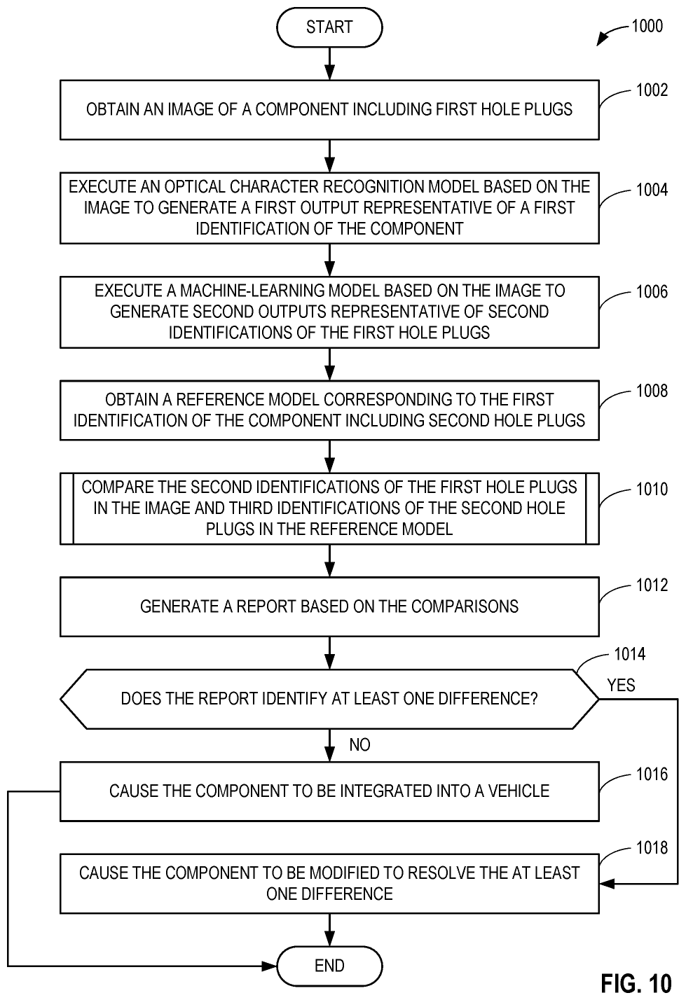

FIG. 10 is a flowchart representative of example machine readable instructions and/or example operations 1000 that may be executed and/or instantiated by processor circuitry to validate hole plug placement for an aircraft component. The example machine readable instructions and/or the example operations 1000 of FIG. 10 begin at block 1002, at which the component verification circuitry 200 obtains an image of a component including first hole plugs. For example, the interface circuitry 210 (FIG. 2) can obtain the component image(s) 278 (FIG. 2) from an image source, such as the camera 116 of FIG. 1. In some examples, the component image(s) 278 can be image(s) of a first one of the components 106 of FIG. 1, which can be the first aircraft doubler 501A of FIG. 5.

At block 1004, the component verification circuitry 200 executes an optical character recognition model based on the image to generate a first output representative of a first identification of the component. For example, the data extraction circuitry 220 (FIG. 2) can execute and/or instantiate one of the OCR model(s) 276 (FIG. 2) on the component image(s) 278 to generate an output representative of an identification of the first aircraft doubler 501A. For example, the data extraction circuitry 220 can identify the first aircraft doubler 501A based on a detection of text that identifies the first aircraft doubler 501A, a bar code (or any other code such as a QR code) that corresponds to an identification of the first aircraft doubler 501A, etc.

At block 1006, the component verification circuitry 200 executes a machine-learning model based on the image to generate second outputs representative of second identifications of the first hole plugs. For example, the machine-learning circuitry 230 (FIG. 2) can execute and/or instantiate the machine-learning model(s) 274 (FIG. 2) based on the component image(s) 278 as model input(s) to generate model output(s), which can include identifications of one or more hole plugs (and/or color(s) thereof) in the first aircraft doubler 501A as depicted in the component image(s) 278.

At block 1008, the component verification circuitry 200 obtains a reference model corresponding to the first identification of the component including second hole plugs. For example, the data extraction circuitry 220 can identify one of the reference model(s) 272 (FIG. 2), such as a reference model as depicted in FIGS. 6 and/or 7, that corresponds to the identification of the first aircraft doubler 501A. In some examples, the data extraction circuitry 220 can identify the one of the reference model(s) 272 based on a data association stored in the datastore 270 (FIG. 2) of the one of the reference model(s) 272 and the identification of the first aircraft doubler 501A.

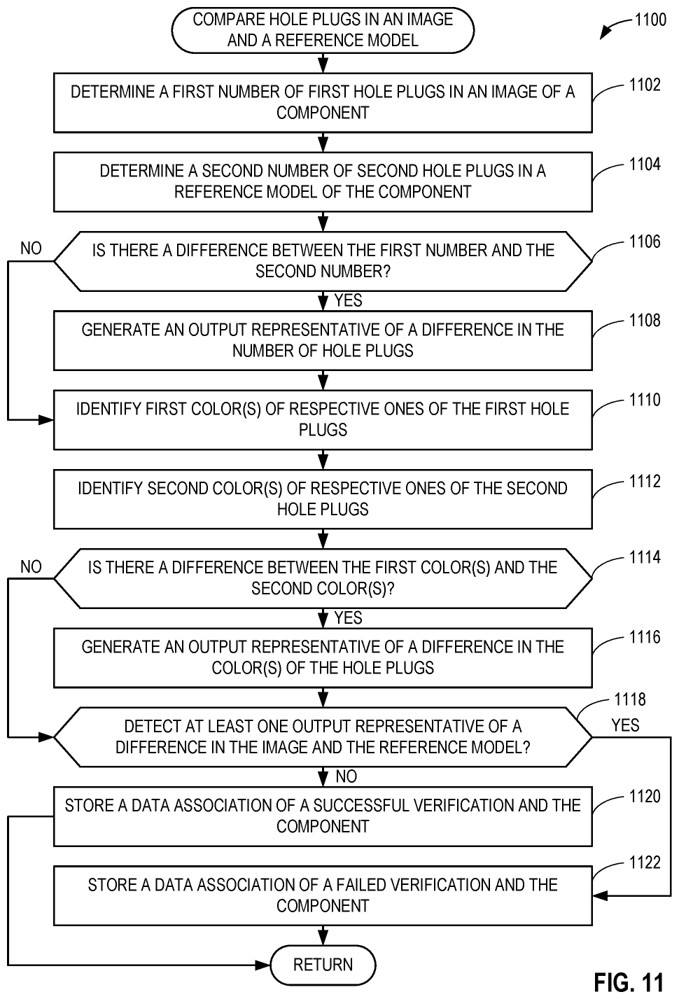

At block 1010, the component verification circuitry 200 compares the second identifications of the first hole plugs in the image and third identifications of the second hole plugs in the reference model. For example, the difference determination circuitry 240 (FIG. 2) can compare a first number of first hole plugs in the component image(s) 278 and a second number of second hole plugs in the one of the reference model(s) 272. In some examples, the difference determination circuitry 240 can compare first color(s) of the first hole plugs and second color(s) of the second hole plugs. An example process that may be executed and/or instantiated to implement block 1010 of FIG. 10 is described below in connection with FIG. 11.

At block 1012, the component verification circuitry 200 generates a report based on the comparisons. For example, the report generation circuitry 250 (FIG. 2) can generate the report(s) 280 (FIG. 2) based on the comparisons. In some examples, the report generation circuitry 250 can generate the report(s) 280 to include, identify, and/or specify differences between the first and second number of hole plugs, the first color(s) and the second color(s), etc.

At block 1014, the component verification circuitry 200 determines whether the report identifies at least one difference. For example, the report generation circuitry 250 can determine that the report(s) 280 indicate differences between the first and second number of hole plugs, the first color(s) and the second color(s), etc. If, at block 1014, the component verification circuitry 200 determines that there is not at least one difference between the hole plugs in the component image(s) 278 and the hole plugs in the one of the reference model(s) 272, control proceeds to block 1016.

At block 1016, the component verification circuitry 200 causes the component to be integrated into a vehicle. For example, the operation control circuitry 260 can flag, identify, etc., the first aircraft doubler 501A to undergo one or more subsequent manufacturing operations, such as painting the first aircraft doubler 501A, coupling the first aircraft doubler 501A to the aircraft 500 of FIG. 5, etc., based on a determination that there are no differences between the hole plugs in the component image(s) 278 and the hole plugs in the one of the reference model(s) 272. After causing the component to be integrated into a vehicle at block 1016, the example machine-readable instructions and/or the example operations 1000 of FIG. 10 conclude.

If, at block 1014, the component verification circuitry 200 determines that there is at least one difference between the hole plugs in the component image(s) 278 and the hole plugs in the one of the reference model(s) 272, control proceeds to block 1018. At block 1018, the component verification circuitry 200 causes the component to be modified to resolve the at least one difference. For example, the operation control circuitry 260 can generate a command (e.g., a human and/or machine-readable command), a direction (e.g., a human and/or machine-readable direction), an instruction (e.g., a human and/or machine-readable instruction), etc., to cause a human and/or machine operator to modify the first aircraft doubler 501A with respect to hole plugs. For example, the operation control circuitry 260 can cause and/or invoke the human and/or machine operator to add a previously missing hole plug, replace a first hole plug of a first color with a second hole of a second color, etc. After causing the component to be modified to resolve the at least one difference at block 1018, the example machine-readable instructions and/or the example operations 1000 of FIG. 10 conclude.

FIG. 11 is a flowchart representative of example machine readable instructions and/or example operations 1100 that may be executed and/or instantiated by processor circuitry to compare hole plugs in an image and a reference model. In some examples, the example machine readable instructions and/or the example operations 1100 of FIG. 11 can be executed and/or instantiated to implement block 1010 of FIG. 10. The example machine readable instructions and/or the example operations 1100 of FIG. 11 begin at block 1102, at which the component verification circuitry 200 determines a first number of first hole plugs in an image of a component. For example, the machine-learning circuitry 230 (FIG. 2) can execute and/or instantiate the machine-learning model(s) 274 to implement machine vision on the component image(s) 278 (FIG. 2) of the first aircraft doubler 501A of FIG. 5 to determine a first number of first hole plugs in the first aircraft doubler 501A as depicted in the component image(s) 278.

At block 1104, the component verification circuitry 200 determines a second number of second hole plugs in a reference model of the component. For example, the data extraction circuitry 220 (FIG. 2) can execute and/or instantiate the OCR model(s) 276 (FIG. 2) on the component image(s) 278 of the first aircraft doubler 501A to extract code(s), symbol(s), text, etc., which identify the first aircraft doubler 501A. In some examples, the data extraction circuitry 220 can determine that one of the reference model(s) 272 corresponds to the identification of the first aircraft doubler 501A. In some examples, the data extraction circuitry 220 can extract information from the one of the reference model(s) 272, such as a second number of second hole plugs in the reference model(s) 272 of the first aircraft doubler 501A.

At block 1106, the component verification circuitry 200 determines whether there is a difference between the first number and the second number. For example, the difference determination circuitry 240 can determine whether the first number of hole plugs is the same or different than the second number of hole plugs.

If, at block 1106, the component verification circuitry 200 determines that there is not a difference between the first number and the second number, control proceeds to block 1110. If, at block 1106, the component verification circuitry 200 determines that there is a difference between the first number and the second number, control proceeds to block 1108.

At block 1108, the component verification circuitry 200 generates an output representative of a difference in the number of hole plugs. For example, the difference determination circuitry 240 can generate a first output representative of a difference between the first number of hole plugs and the second number of hole plugs, which can be indicative that at least one full-sized hole in the first aircraft doubler 501A is missing a hole plug.

At block 1110, the component verification circuitry 200 identifies first color(s) of respective ones of the first hole plugs. For example, the machine-learning circuitry 230 can execute and/or instantiate the machine-learning model(s) 274 to implement machine vision on the component image(s) 278 of the first aircraft doubler 501A of FIG. 5 to determine first respective colors of the first hole plugs in the first aircraft doubler 501A as depicted in the component image(s) 278.

At block 1112, the component verification circuitry 200 identifies second color(s) of respective ones of the second hole plugs. For example, the data extraction circuitry 220 can extract information from the one of the reference model(s) 272, such as second respective colors of the second hole plugs in the reference model(s) 272 of the first aircraft doubler 501A.

At block 1114, the component verification circuitry 200 determines whether there is a difference between the first color(s) and the second color(s). For example, the difference determination circuitry 240 can determine whether one(s) of the first respective colors of the first hole plugs is/are different than the second respective colors of the second hole plugs.

If, at block 1114, the component verification circuitry 200 determines that there is not a difference between the first color(s) and the second color(s), control proceeds to block 1118. If, at block 1114, the component verification circuitry 200 determines that there is a difference between the first color(s) and the second color(s), control proceeds to block 1116.

At block 1116, the component verification circuitry 200 generates an output representative of a difference in the color(s) of the hole plugs. For example, the difference determination circuitry 240 can generate a second output representative of a difference between the first respective colors of the first hole plugs and the second respective colors of the second hole plugs, which can be indicative that at least one hole plug is incorrectly utilized.

At block 1118, the component verification circuitry 200 detects whether there is at least one output representative of a difference in the image and the reference model. For example, the difference determination circuitry 240 can detect and/or otherwise determine whether there is/are differences between the number of hole plugs and/or color(s) thereof in the component image(s) 278 and the one of the reference model(s) 272.

If, at block 1118, the component verification circuitry 200 detects that there is not at least one output representative of a difference in the image and the reference model, control proceeds to block 1120. At block 1120, the component verification circuitry 200 stores a data association of a successful verification and the component. For example, the report generation circuitry 250 (FIG. 2) can generate a first data association that is representative of the first aircraft doubler 501A being successfully verified against applicable requirements, standards, specifications, etc., that govern and/or otherwise define how the first aircraft doubler 501A is to be manufactured (e.g., manufactured based on FSDA principles or techniques). In some examples, the report generation circuitry 250 can store the first data association as and/or part of the report(s) 280 (FIG. 2) in the datastore 270 (FIG. 2). After storing a data association of a successful verification and the component at block 1120, the example machine-readable instructions and/or the example operations 1100 of FIG. 11 conclude. For example, the machine-readable instructions and/or the operations 1100 of FIG. 11 can return to block 1012 of the machine-readable instructions and/or the operations 1000 of FIG. 10 to generate a report based on the comparisons.

If, at block 1118, the component verification circuitry 200 detects that there is at least one output representative of a difference in the image and the reference model, control proceeds to block 1122. At block 1122, the component verification circuitry 200 stores a data association of a failed verification and the component. For example, the report generation circuitry 250 can generate a second data association that is representative of the first aircraft doubler 501A not being successfully verified against applicable requirements, standards, specifications, etc., that govern and/or otherwise define how the first aircraft doubler 501A is to be manufactured (e.g., manufactured based on FSDA principles or techniques). In some examples, the report generation circuitry 250 can store the second data association as and/or part of the report(s) 280 in the datastore 270. After storing a data association of a failed and/or otherwise unsuccessful verification and the component at block 1122, the example machine-readable instructions and/or the example operations 1100 of FIG. 11 conclude. For example, the machine-readable instructions and/or the operations 1100 of FIG. 11 can return to block 1012 of the machine-readable instructions and/or the operations 1000 of FIG. 10 to generate a report based on the comparisons.

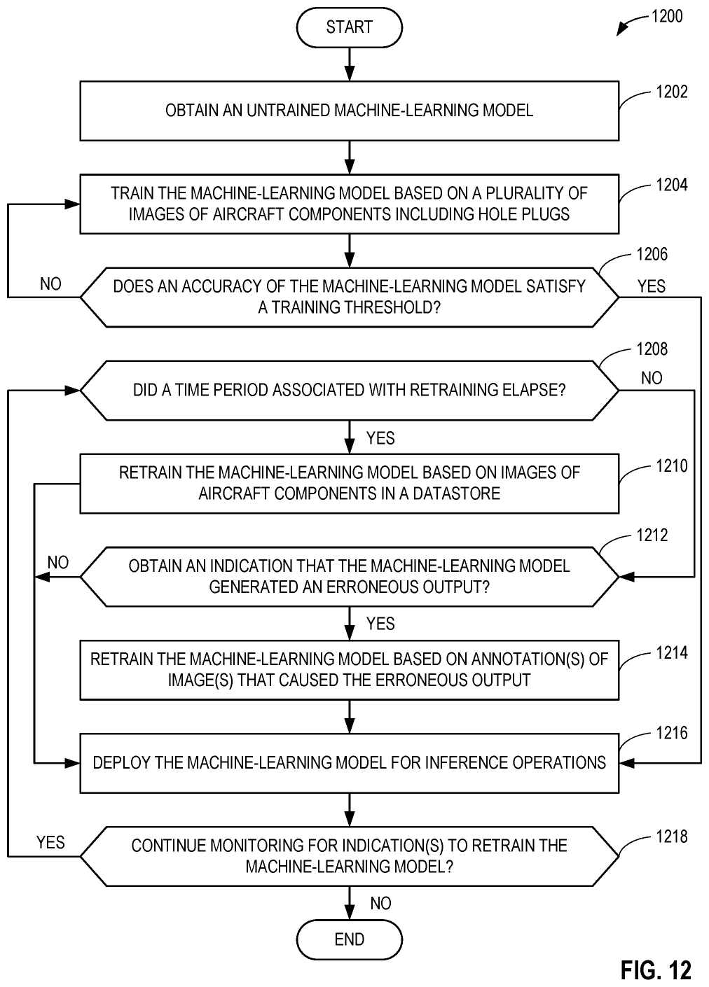

FIG. 12 is a flowchart representative of example machine readable instructions and/or example operations 1200 that may be executed and/or instantiated by processor circuitry to train a machine-learning model to validate hole plug placement for an aircraft component. The example machine readable instructions and/or the example operations 1200 of FIG. 12 begin at block 1202, at which the component verification circuitry 200 obtains an untrained machine-learning model. For example, the interface circuitry 210 (FIG. 2) can obtain (e.g., obtain via a network, obtain from a datastore, etc.) an untrained one of the machine-learning model(s) 274.

At block 1204, the component verification circuitry 200 trains the machine-learning model based on a plurality of images of aircraft components including hole plugs. For example, the machine-learning circuitry 230 (FIG. 2) can train the untrained one of the machine-learning model(s) 274 using training data, which can include the component image(s) 278 (FIG. 2).

At block 1206, the component verification circuitry 200 determines whether an accuracy of the machine-learning model satisfies a training threshold. For example, the machine-learning circuitry 230 can determine whether an output of the one of the machine-learning model(s) 274 undergoing training has an accuracy (e.g., a probability or likelihood that the output is accurate or correct) that is greater than an accuracy or training threshold (e.g., an accuracy threshold of 0.8 probability, 80% likelihood, etc.).

If, at block 1206, the component verification circuitry 200 determines that an accuracy of the machine-learning model does not satisfy a training threshold, control returns to block 1204 to continue retraining the one of the machine-learning model(s) 274.

If, at block 1206, the component verification circuitry 200 determines that an accuracy of the machine-learning model satisfies a training threshold, control proceeds to block 1216. At block 1216, the component verification circuitry 200 deploys the machine-learning model for inference operations. For example, the machine-learning circuitry 230 can store the trained one of the machine-learning model(s) 274 in the datastore 270. In some examples, the machine-learning circuitry 230 can enable the trained one of the machine-learning model(s) 274 to be available for download to a client device (e.g., a computing and/or electronic device associated with the camera 116 of FIG. 1). In some examples, the machine-learning circuitry 230 can cause transmission of the trained one of the machine-learning model(s) 274 to the client device (e.g., via the network 118 of FIG. 1).

At block 1218, the component verification circuitry 200 determines whether to continue monitoring for indication(s) to retrain the machine-learning model. For example, the interface circuitry 210 can determine whether to continue evaluating whether a time period associated with retraining the machine-learning model(s) 274 has elapsed.

If, at block 1218, the component verification circuitry 200 determines to continue monitoring for indication(s) to retrain the machine-learning model, control returns to block 1208. At block 1208, the component verification circuitry 200 determines whether a time period associated with retraining elapsed. For example, the machine-learning circuitry 230 can determine to retrain the machine-learning model(s) 274 every day, every week, every month, etc., or any other period of time.

If, at block 1208, the component verification circuitry 200 determines that a time period associated with retraining has elapsed, control proceeds to block 1210. At block 1210, the component verification circuitry 200 retrains the machine-learning model based on images of aircraft components in a datastore. For example, the machine-learning circuitry 230 can retrain one(s) of the machine-learning model(s) 274 based on the component image(s) 278 in the datastore 270 or any other component image(s). After retraining the machine-learning model based on images of aircraft components in a datastore, control proceeds to block 1216.

If, at block 1208, the component verification circuitry 200 determines whether a time period associated with retraining has not elapsed, control proceeds to block 1212. At block 1212, the component verification circuitry 200 determines whether an indication that the machine-learning model generated an erroneous output is obtained. For example, the interface circuitry 210 can obtain a data message generated by the operator 122 of FIG. 1 that indicates that an output of the machine-learning model(s) 274 is inaccurate. For example, the data message can be one or more of a table, a grid, a packet, a datagram, a frame, a file, an e-mail, a message, a document, a report, a list, or any other form of data representation. In some examples, the indication can be that a number of detected hole plugs in the component image(s) 278 is incorrect, a color of a hole plug is incorrectly identified (e.g., a hole plug is identified as a blue hole plug instead of a red hole plug).

If, at block 1212, the component verification circuitry 200 determines that an indication that the machine-learning model generated an erroneous output is not obtained, control proceeds to block 1216. If, at block 1212, the component verification circuitry 200 determines that an indication that the machine-learning model generated an erroneous output is obtained, control proceeds to block 1214.

At block 1214, the component verification circuitry 200 retrains the machine-learning model based on annotation(s) of image(s) that caused the erroneous output. For example, the machine-learning circuitry 230 can retrain the machine-learning model(s) 274 that produced the erroneous output(s) flagged by the operator 122 using annotations, corrections, notes, etc., generated by the operator 122 (e.g., annotations, corrections, notes, etc., included in the data message generated by the operator 122).

If, at block 1218, the component verification circuitry 200 determines not to continue monitoring for indication(s) to retrain the machine-learning model, the example machine-readable instructions and/or the example operations 1200 of FIG. 12 conclude.

FIG. 13 is a block diagram of an example processor platform 1300 structured to execute and/or instantiate the example machine readable instructions and/or the example operations of FIGS. 9-12 to implement the component verification circuitry 200 of FIG. 2. The processor platform 1300 can be, for example, a server, a personal computer, a workstation, a self-learning machine (e.g., a neural network), a mobile device (e.g., a cell phone, a smart phone, a tablet such as an iPad™), a headset (e.g., an augmented reality (AR) headset, a virtual reality (VR) headset, etc.) or other wearable device, or any other type of computing device.

The processor platform 1300 of the illustrated example includes processor circuitry 1312. The processor circuitry 1312 of the illustrated example is hardware. For example, the processor circuitry 1312 can be implemented by one or more integrated circuits, logic circuits, FPGAs, microprocessors, CPUs, GPUs, DSPs, and/or microcontrollers from any desired family or manufacturer. The processor circuitry 1312 may be implemented by one or more semiconductor based (e.g., silicon based) devices. In this example, the processor circuitry 1312 implements the data extraction circuitry 220, the machine-learning circuitry 230 (identified by ML CIRCUITRY), the difference determination circuitry 240 (identified by DIFF DETERM CIRCUITRY), the report generation circuitry 250 (identified by REPORT GEN CIRCUITRY), and the operation control circuitry 260 (identified by OPERATION CTRL CIRCUITRY) of FIG. 2.

The processor circuitry 1312 of the illustrated example includes a local memory 1313 (e.g., a cache, registers, etc.). The processor circuitry 1312 of the illustrated example is in communication with a main memory including a volatile memory 1314 and a non-volatile memory 1316 by a bus 1318. In some examples, the bus 1318 can implement the bus 290 of FIG. 2. The volatile memory 1314 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1316 may be implemented by flash memory and/or any other desired type of memory device. Access to the main memory 1314, 1316 of the illustrated example is controlled by a memory controller 1317.

The processor platform 1300 of the illustrated example also includes interface circuitry 1320. In this example, the interface circuitry 1320 implements the interface circuitry 210 of FIG. 2. The interface circuitry 1320 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1322 are connected to the interface circuitry 1320. The input device(s) 1322 permit(s) a user to enter data and/or commands into the processor circuitry 1312. The input device(s) 1322 can be implemented by, for example, an audio sensor, a microphone, a camera (still or video), a keyboard, a button, a mouse, a touchscreen, a track-pad, a trackball, an isopoint device, and/or a voice recognition system.

One or more output devices 1324 are also connected to the interface circuitry 1320 of the illustrated example. The output device(s) 1324 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1320 of the illustrated example, thus, typically includes a graphics driver card, a graphics driver chip, and/or graphics processor circuitry such as a GPU.

The interface circuitry 1320 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1326. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 1300 of the illustrated example also includes one or more mass storage devices 1328 to store software and/or data. In this example, the one or more mass storage devices 1328 implement the datastore 270, the reference model(s) 272 (identified by REF MODEL(S)), the machine-learning model(s) 274 (identified by ML MODEL(S)), the OCR model(s) 276, the component image(s) 278 (identified by IMAGE(S) 278), and the report(s) 280 of FIG. 2. Examples of such mass storage devices 1328 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives.

The machine readable instructions 1332, which may be implemented by the machine readable instructions of FIGS. 9-13, may be stored in the mass storage device 1328, in the volatile memory 1314, in the non-volatile memory 1316, and/or on a removable non-transitory computer readable storage medium such as a CD or DVD.

The processor platform 1300 of the illustrated example of FIG. 13 includes example acceleration circuitry 1340, which includes an example graphics processor unit (GPU) 1342, an example vision processor unit (VPU) 1344, and an example neural network processor 1346. In this example, the GPU 1342, the VPU 1344, and the neural network processor 1346 are in communication with different hardware of the processor platform 1300, such as the volatile memory 1314, the non-volatile memory 1316, etc., via the bus 1318. In this example, the neural network processor 1346 may be implemented by one or more integrated circuits, logic circuits, microprocessors, GPUs, DSPs, or controllers from any desired family or manufacturer that can be used to execute an AI model, such as a neural network, which may be implemented by the machine-learning model(s) 274. In some examples, one or more of the data extraction circuitry 220, the machine-learning circuitry 230, the difference determination circuitry 240, the report generation circuitry 250, and the operation control circuitry 260 of FIG. 2 can be implemented in or with at least one of the GPU 1342, the VPU 1344, or the neural network processor 1346 instead of or in addition to the processor circuitry 1312.

FIG. 14 is a block diagram of an example implementation of the processor circuitry 1312 of FIG. 13. In this example, the processor circuitry 1312 of FIG. 13 is implemented by a microprocessor 1400. For example, the microprocessor 1400 may be a general purpose microprocessor (e.g., general purpose microprocessor circuitry). The microprocessor 1400 executes some or all of the machine readable instructions of the flowcharts of FIGS. 9-12 to effectively instantiate the component verification circuitry 200 of FIG. 2 as logic circuits to perform the operations corresponding to those machine readable instructions. In some such examples, the component verification circuitry 200 is instantiated by the hardware circuits of the microprocessor 1400 in combination with the instructions. For example, the microprocessor 1400 may be implemented by multi-core hardware circuitry such as a CPU, a DSP, a GPU, an XPU, etc. Although it may include any number of example cores 1402 (e.g., 1 core), the microprocessor 1400 of this example is a multi-core semiconductor device including N cores. The cores 1402 of the microprocessor 1400 may operate independently or may cooperate to execute machine readable instructions. For example, machine code corresponding to a firmware program, an embedded software program, or a software program may be executed by one of the cores 1402 or may be executed by multiple ones of the cores 1402 at the same or different times. In some examples, the machine code corresponding to the firmware program, the embedded software program, or the software program is split into threads and executed in parallel by two or more of the cores 1402. The software program may correspond to a portion or all of the machine readable instructions and/or operations represented by the flowcharts of FIGS. 9-12.

The cores 1402 may communicate by a first example bus 1404. In some examples, the first bus 1404 may be implemented by a communication bus to effectuate communication associated with one(s) of the cores 1402. For example, the first bus 1404 may be implemented by at least one of an Inter-Integrated Circuit (I2C) bus, a Serial Peripheral Interface (SPI) bus, a PCI bus, or a PCIe bus. Additionally or alternatively, the first bus 1404 may be implemented by any other type of computing or electrical bus. The cores 1402 may obtain data, instructions, and/or signals from one or more external devices by example interface circuitry 1406. The cores 1402 may output data, instructions, and/or signals to the one or more external devices by the interface circuitry 1406. Although the cores 1402 of this example include example local memory 1420 (e.g., Level 1 (L1) cache that may be split into an L1 data cache and an L1 instruction cache), the microprocessor 1400 also includes example shared memory 1410 that may be shared by the cores (e.g., Level 2 (L2 cache)) for high-speed access to data and/or instructions. Data and/or instructions may be transferred (e.g., shared) by writing to and/or reading from the shared memory 1410. The local memory 1420 of each of the cores 1402 and the shared memory 1410 may be part of a hierarchy of storage devices including multiple levels of cache memory and the main memory (e.g., the main memory 1314, 1316 of FIG. 13). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1402 may be referred to as a CPU, DSP, GPU, etc., or any other type of hardware circuitry. Each core 1402 includes control unit circuitry 1414, arithmetic and logic (AL) circuitry (sometimes referred to as an ALU) 1416, a plurality of registers 1418, the local memory 1420, and a second example bus 1422. Other structures may be present. For example, each core 1402 may include vector unit circuitry, single instruction multiple data (SIMD) unit circuitry, load/store unit (LSU) circuitry, branch/jump unit circuitry, floating-point unit (FPU) circuitry, etc. The control unit circuitry 1414 includes semiconductor-based circuits structured to control (e.g., coordinate) data movement within the corresponding core 1402. The AL circuitry 1416 includes semiconductor-based circuits structured to perform one or more mathematic and/or logic operations on the data within the corresponding core 1402. The AL circuitry 1416 of some examples performs integer based operations. In other examples, the AL circuitry 1416 also performs floating point operations. In yet other examples, the AL circuitry 1416 may include first AL circuitry that performs integer based operations and second AL circuitry that performs floating point operations. In some examples, the AL circuitry 1416 may be referred to as an Arithmetic Logic Unit (ALU). The registers 1418 are semiconductor-based structures to store data and/or instructions such as results of one or more of the operations performed by the AL circuitry 1416 of the corresponding core 1402. For example, the registers 1418 may include vector register(s), SIMD register(s), general purpose register(s), flag register(s), segment register(s), machine specific register(s), instruction pointer register(s), control register(s), debug register(s), memory management register(s), machine check register(s), etc. The registers 1418 may be arranged in a bank as shown in FIG. 14. Alternatively, the registers 1418 may be organized in any other arrangement, format, or structure including distributed throughout the core 1402 to shorten access time. The second bus 1422 may be implemented by at least one of an I2C bus, a SPI bus, a PCI bus, or a PCIe bus

Each core 1402 and/or, more generally, the microprocessor 1400 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1400 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

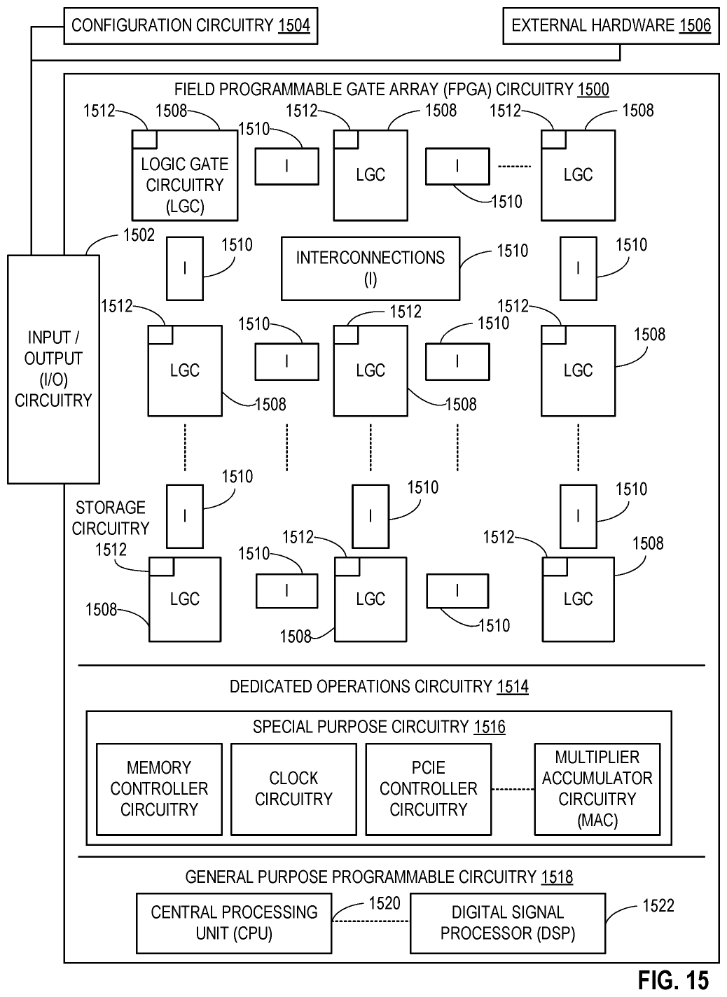

FIG. 15 is a block diagram of another example implementation of the processor circuitry 1312 of FIG. 13. In this example, the processor circuitry 412 is implemented by FPGA circuitry 1500. For example, the FPGA circuitry 1500 may be implemented by an FPGA. The FPGA circuitry 1500 can be used, for example, to perform operations that could otherwise be performed by the example microprocessor 1400 of FIG. 14 executing corresponding machine readable instructions. However, once configured, the FPGA circuitry 1500 instantiates the machine readable instructions in hardware and, thus, can often execute the operations faster than they could be performed by a general purpose microprocessor executing the corresponding software.

More specifically, in contrast to the microprocessor 1400 of FIG. 14 described above (which is a general purpose device that may be programmed to execute some or all of the machine readable instructions represented by the flowcharts of FIGS. 9-12 but whose interconnections and logic circuitry are fixed once fabricated), the FPGA circuitry 1500 of the example of FIG. 15 includes interconnections and logic circuitry that may be configured and/or interconnected in different ways after fabrication to instantiate, for example, some or all of the machine readable instructions represented by the flowcharts of FIGS. 9-12. In particular, the FPGA circuitry 1500 may be thought of as an array of logic gates, interconnections, and switches. The switches can be programmed to change how the logic gates are interconnected by the interconnections, effectively forming one or more dedicated logic circuits (unless and until the FPGA circuitry 1500 is reprogrammed). The configured logic circuits enable the logic gates to cooperate in different ways to perform different operations on data received by input circuitry. Those operations may correspond to some or all of the software represented by the flowcharts of FIGS. 9-12. As such, the FPGA circuitry 1500 may be structured to effectively instantiate some or all of the machine readable instructions of the flowchart of FIGS. 9-12 as dedicated logic circuits to perform the operations corresponding to those software instructions in a dedicated manner analogous to an ASIC. Therefore, the FPGA circuitry 1500 may perform the operations corresponding to the some or all of the machine readable instructions of FIG. _ faster than the general purpose microprocessor can execute the same.

In the example of FIG. 15, the FPGA circuitry 1500 is structured to be programmed (and/or reprogrammed one or more times) by an end user by a hardware description language (HDL) such as Verilog. The FPGA circuitry 1500 of FIG. 15, includes example input/output (I/O) circuitry 1502 to obtain and/or output data to/from example configuration circuitry 1504 and/or external hardware 1506. For example, the configuration circuitry 1504 may be implemented by interface circuitry that may obtain machine readable instructions to configure the FPGA circuitry 1500, or portion(s) thereof. In some such examples, the configuration circuitry 1504 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 1506 may be implemented by external hardware circuitry. For example, the external hardware 1506 may be implemented by the microprocessor 1400 of FIG. 14. The FPGA circuitry 1500 also includes an array of example logic gate circuitry 1508, a plurality of example configurable interconnections 1510, and example storage circuitry 1512. The logic gate circuitry 1508 and the configurable interconnections 1510 are configurable to instantiate one or more operations that may correspond to at least some of the machine readable instructions of FIGS. 9-12 and/or other desired operations. The logic gate circuitry 1508 shown in FIG. 15 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1508 to enable configuration of the electrical structures and/or the logic gates to form circuits to perform desired operations. The logic gate circuitry 1508 may include other electrical structures such as look-up tables (LUTs), registers (e.g., flip-flops or latches), multiplexers, etc.

The configurable interconnections 1510 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1508 to program desired logic circuits.

The storage circuitry 1512 of the illustrated example is structured to store result(s) of the one or more of the operations performed by corresponding logic gates. The storage circuitry 1512 may be implemented by registers or the like. In the illustrated example, the storage circuitry 1512 is distributed amongst the logic gate circuitry 1508 to facilitate access and increase execution speed.

The example FPGA circuitry 1500 of FIG. 15 also includes example Dedicated Operations Circuitry 1514. In this example, the Dedicated Operations Circuitry 1514 includes special purpose circuitry 1516 that may be invoked to implement commonly used functions to avoid the need to program those functions in the field. Examples of such special purpose circuitry 1516 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1500 may also include example general purpose programmable circuitry 1518 such as an example CPU 1520 and/or an example DSP 1522. Other general purpose programmable circuitry 1518 may additionally or alternatively be present such as a GPU, an XPU, etc., that can be programmed to perform other operations.

Although FIGS. 14 and 15 illustrate two example implementations of the processor circuitry 1312 of FIG. 13, many other approaches are contemplated. For example, as mentioned above, modern FPGA circuitry may include an on-board CPU, such as one or more of the example CPU 1520 of FIG. 15. Therefore, the processor circuitry 1312 of FIG. 13 may additionally be implemented by combining the example microprocessor 1400 of FIG. 14 and the example FPGA circuitry 1500 of FIG. 15. In some such hybrid examples, a first portion of the machine readable instructions represented by the flowcharts of FIGS. 9-12 may be executed by one or more of the cores 1402 of FIG. 14, a second portion of the machine readable instructions represented by the flowcharts of FIGS. 9-12 may be executed by the FPGA circuitry 1500 of FIG. 15, and/or a third portion of the machine readable instructions represented by the flowcharts of FIGS. 9-12 may be executed by an ASIC. It should be understood that some or all of the component verification circuitry 200 of FIG. 2 may, thus, be instantiated at the same or different times. Some or all of the circuitry may be instantiated, for example, in one or more threads executing concurrently and/or in series. Moreover, in some examples, some or all of the component verification circuitry 200 of FIG. 2 may be implemented within one or more virtual machines and/or containers executing on the microprocessor.

In some examples, the processor circuitry 1312 of FIG. 13 may be in one or more packages. For example, the microprocessor 1400 of FIG. 14 and/or the FPGA circuitry 1500 of FIG. 15 may be in one or more packages. In some examples, an XPU may be implemented by the processor circuitry 1312 of FIG. 13, which may be in one or more packages. For example, the XPU may include a CPU in one package, a DSP in another package, a GPU in yet another package, and an FPGA in still yet another package.

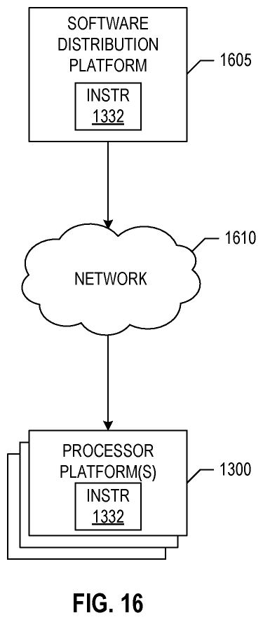

A block diagram illustrating an example software distribution platform 1605 to distribute software such as the example machine readable instructions 1332 of FIG. 13 to hardware devices owned and/or operated by third parties is illustrated in FIG. 16. The example software distribution platform 1605 may be implemented by any computer server, data facility, cloud service, etc., capable of storing and transmitting software to other computing devices. The third parties may be customers of the entity owning and/or operating the software distribution platform 1605. For example, the entity that owns and/or operates the software distribution platform 1605 may be a developer, a seller, and/or a licensor of software such as the example machine readable instructions 1332 of FIG. 13. The third parties may be consumers, users, retailers, OEMs, etc., who purchase and/or license the software for use and/or re-sale and/or sub-licensing. In the illustrated example, the software distribution platform 1605 includes one or more servers and one or more storage devices. The storage devices store the machine readable instructions 1332, which may correspond to the example machine readable instructions 900, 1000, 1100, 1200 of FIGS. 9-12, as described above. The one or more servers of the example software distribution platform 1605 are in communication with an example network 1610, which may correspond to any one or more of the Internet and/or any of the example networks 118, 1326 described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 1332 from the software distribution platform 1605. For example, the software, which may correspond to the example machine readable instructions 900, 1000, 1100, 1200 of FIGS. 9-12, may be downloaded to the example processor platform 1300, which is to execute the machine readable instructions 1332 to implement the component verification circuitry 200 of FIG. 2. In some examples, one or more servers of the software distribution platform 1605 periodically offer, transmit, and/or force updates to the software (e.g., the example machine readable instructions 1332 of FIG. 13) to ensure improvements, patches, updates, etc., are distributed and applied to the software at the end user devices.

From the foregoing, it will be appreciated that example systems, apparatus, articles of manufacture, and methods have been disclosed for machine-learning based hole plug validation. Disclosed systems, apparatus, articles of manufacture, and methods improve the efficiency of using a computing device by reducing a number of man hours required to analyze images of component hole plugs. Disclosed systems, apparatus, articles of manufacture, and methods can verify and/or validate component hole plug placement with increased efficiency compared to manual verification and/or validation by requiring compute, memory, mass storage, etc., processor platform resources for less time than may have previously been needed for the manual verification and/or validation. Disclosed systems, methods, apparatus, and articles of manufacture are accordingly directed to one or more improvement(s) in the operation of a machine such as a computer or other electronic and/or mechanical device.

Example systems, apparatus, articles of manufacture, and methods for machine-learning based hole plug validation are disclosed herein. Further examples and combinations thereof include the following:

Example 1 includes an apparatus comprising at least one memory, machine-readable instructions, and processor circuitry to at least one of execute or instantiate the machine-readable instructions to at least execute a machine-learning model based on an image of an aircraft component to generate an output representative of first identifications of first hole plugs in the aircraft component, determine one or more differences between the first identifications of the first hole plugs in the image and second identifications of second hole plugs in a reference model of the aircraft component, and cause an operation associated with an aircraft to occur based on the one or more differences.

Example 2 includes the apparatus of example 1, wherein the output is a first output, and the processor circuitry is to execute an optical character recognition model based on the image to generate a second output representative of a third identification of the aircraft component.

Example 3 includes the apparatus of example 2, wherein the processor circuitry is to identify the reference model in a datastore based on a data association between the third identification of the aircraft component and the reference model.

Example 4 includes the apparatus of example 1, wherein the operation is a modification of the aircraft component, and the processor circuitry is to generate a report based on the comparisons, and after a determination that the report identifies the one or more differences, cause the modification of the aircraft component to resolve the one or more differences.

Example 5 includes the apparatus of example 1, wherein the operation is an integration of the aircraft component into the aircraft, and the processor circuitry is to generate a report based on the comparisons, and after a determination that the report does not identify at least one difference, cause the integration of the aircraft component into the aircraft.

Example 6 includes the apparatus of example 1, wherein the output is a first output, the first identifications include a first number of hole plugs, the second identifications include a second number of hole plugs, and the processor circuitry is to generate a second output to be representative of a difference between the first number of hole plugs and the second number of hole plugs, determine the one or more differences based on the second output, and store a data association of a failed verification and the aircraft component based on the one or more differences.

Example 7 includes the apparatus of example 1, wherein the output is a first output, the first identifications include a first number of hole plugs, the second identifications include a second number of hole plugs, and the processor circuitry is to generate a second output to be representative of a difference between the first number of hole plugs and the second number of hole plugs, determine that the first number of hole plugs and the second number of hole plugs is the same based on the second output, and store a data association of a successful verification and the aircraft component based on the first number of hole plugs and the second number of hole plugs being the same.

Example 8 includes the apparatus of example 1, wherein the output is a first output, the first identifications include a color of respective ones of the first hole plugs, the second identifications include a color of respective ones of the second hole plugs, and the processor circuitry is to generate a second output to be representative of a difference between the color of the respective ones of the first hole plugs and the color of the respective ones of the second hole plugs, determine the one or more differences based on the second output, and store a data association of a failed verification and the aircraft component based on the one or more differences.

Example 9 includes the apparatus of example 1, wherein the output is a first output, the first identifications include a color of respective ones of the first hole plugs, the second identifications include a color of respective ones of the second hole plugs, and the processor circuitry is to generate a second output to be representative of a difference between the color of the respective ones of the first hole plugs and the color of the respective ones of the second hole plugs, determine the color of the respective ones of the first hole plugs and the color of the respective ones of the second hole plugs are the same, and store a data association of a successful verification and the aircraft component based on the color of the respective ones of the first hole plugs and the color of the respective ones of the second hole plugs being the same.

Example 10 includes the apparatus of example 1, wherein the processor circuitry is to train the machine-learning model based on a plurality of images of aircraft components including hole plugs of one or more sizes and one or more colors, and after a determination that an accuracy of the machine-learning model satisfies a training threshold, store the machine-learning model in a datastore for access by an electronic device.

Example 11 includes the apparatus of example 1, wherein the processor circuitry is to train the machine-learning model to identify the aircraft component using a plurality of images of the aircraft component in different orientations or environment conditions.

Example 12 includes the apparatus of example 1, wherein the processor circuitry is to train the machine-learning model to identify the first hole plugs using a plurality of images of the first hole plugs in different orientations or environment conditions.

Example 13 includes the apparatus of example 1, wherein the output is a first output, and the processor circuitry is to obtain the second identifications of the second hole plugs based on second outputs from an automation tool plug-in, the automation tool plug-in to generate the second outputs based on the reference model as an input to the automation tool plug-in.

Example 14 includes the apparatus of example 1, wherein the output is a first output, and the processor circuitry is to determine the second identifications of the second hole plugs from second outputs of the machine-learning model based on the reference model as an input to the machine-learning model.

Example 15 includes the apparatus of example 1, wherein the processor circuitry is to execute the machine-learning model to identify the aircraft component in the image.

Example 16 includes at least one non-transitory computer readable storage medium comprising instructions that, when executed, cause processor circuitry to at least execute a machine-learning model based on an image of an aircraft component to generate an output representative of first identifications of first hole plugs in the aircraft component, determine one or more differences between the first identifications of the first hole plugs in the image and second identifications of second hole plugs in a reference model of the aircraft component, and cause an operation associated with an aircraft to occur based on the one or more differences.

Example 17 includes the at least one non-transitory computer readable storage medium of example 16, wherein the output is a first output, and the instructions are to cause the processor circuitry to execute an optical character recognition model based on the image to generate a second output representative of a third identification of the aircraft component.

Example 18 includes the at least one non-transitory computer readable storage medium of example 17, wherein the instructions are to cause the processor circuitry to identify the reference model in a datastore based on a data association between the third identification of the aircraft component and the reference model.

Example 19 includes the at least one non-transitory computer readable storage medium of example 16, wherein the operation is a modification of the aircraft component, and the instructions are to cause the processor circuitry to generate a report based on the comparisons, and after a determination that the report identifies the one or more differences, cause the modification of the aircraft component to resolve the one or more differences.

Example 20 includes the at least one non-transitory computer readable storage medium of example 16, wherein the operation is an integration of the aircraft component into the aircraft, and the instructions are to cause the processor circuitry to generate a report based on the comparisons, and after a determination that the report does not identify at least one difference, cause the integration of the aircraft component into the aircraft.

Example 21 includes the at least one non-transitory computer readable storage medium of example 16, wherein the output is a first output, the first identifications include a first number of hole plugs, the second identifications include a second number of hole plugs, and the instructions are to cause the processor circuitry to generate a second output to be representative of a difference between the first number of hole plugs and the second number of hole plugs, determine the one or more differences based on the second output, and store a data association of a failed verification and the aircraft component based on the one or more differences.

Example 22 includes the at least one non-transitory computer readable storage medium of example 16, wherein the output is a first output, the first identifications include a first number of hole plugs, the second identifications include a second number of hole plugs, and the instructions are to cause the processor circuitry to generate a second output to be representative of a difference between the first number of hole plugs and the second number of hole plugs, determine that the first number of hole plugs and the second number of hole plugs is the same based on the second output, and store a data association of a successful verification and the aircraft component based on the first number of hole plugs and the second number of hole plugs being the same.

Example 23 includes the at least one non-transitory computer readable storage medium of example 16, wherein the output is a first output, the first identifications include a color of respective ones of the first hole plugs, the second identifications include a color of respective ones of the second hole plugs, and the instructions are to cause the processor circuitry to generate a second output to be representative of a difference between the color of the respective ones of the first hole plugs and the color of the respective ones of the second hole plugs, determine the one or more differences based on the second output, and store a data association of a failed verification and the aircraft component based on the one or more differences.

Example 24 includes the at least one non-transitory computer readable storage medium of example 16, wherein the output is a first output, the first identifications include a color of respective ones of the first hole plugs, the second identifications include a color of respective ones of the second hole plugs, and the instructions are to cause the processor circuitry to generate a second output to be representative of a difference between the color of the respective ones of the first hole plugs and the color of the respective ones of the second hole plugs, determine the color of the respective ones of the first hole plugs and the color of the respective ones of the second hole plugs are the same, and store a data association of a successful verification and the aircraft component based on the color of the respective ones of the first hole plugs and the color of the respective ones of the second hole plugs being the same.

Example 25 includes the at least one non-transitory computer readable storage medium of example 16, wherein the instructions are to cause the processor circuitry to train the machine-learning model based on a plurality of images of aircraft components including hole plugs of one or more sizes and one or more colors, and after a determination that an accuracy of the machine-learning model satisfies a training threshold, store the machine-learning model in a datastore for access by an electronic device.

Example 26 includes the at least one non-transitory computer readable storage medium of example 16, wherein the instructions are to cause the processor circuitry to train the machine-learning model to identify the aircraft component using a plurality of images of the aircraft component in different orientations or environment conditions.

Example 27 includes the at least one non-transitory computer readable storage medium of example 16, wherein the instructions are to cause the processor circuitry to train the machine-learning model to identify the first hole plugs using a plurality of images of the first hole plugs in different orientations or environment conditions.

Example 28 includes the at least one non-transitory computer readable storage medium of example 16, wherein the output is a first output, and the instructions are to cause the processor circuitry to obtain the second identifications of the second hole plugs based on second outputs from an automation tool plug-in, the automation tool plug-in to generate the second outputs based on the reference model as an input to the automation tool plug-in.

Example 29 includes the at least one non-transitory computer readable storage medium of example 16, wherein the output is a first output, and the instructions are to cause the processor circuitry to determine the second identifications of the second hole plugs from second outputs of the machine-learning model based on the reference model as an input to the machine-learning model.

Example 30 includes the at least one non-transitory computer readable storage medium of example 16, wherein the processor circuitry is to execute the machine-learning model to identify the aircraft component in the image.

Example 31 includes a method comprising executing a machine-learning model based on an image of an aircraft component to generate an output representative of first identifications of first hole plugs in the aircraft component, determining one or more differences between the first identifications of the first hole plugs in the image and second identifications of second hole plugs in a reference model of the aircraft component, and causing an operation associated with an aircraft to occur based on the one or more differences.

Example 32 includes the method of example 31, wherein the output is a first output, and the method further includes executing an optical character recognition model based on the image to generate a second output representative of a third identification of the aircraft component.

Example 33 includes the method of example 32, further including identifying the reference model in a datastore based on a data association between the third identification of the aircraft component and the reference model.

Example 34 includes the method of example 31, wherein the operation is a modification of the aircraft component, and the method further including generating a report based on the comparisons, and after a determination that the report identifies the one or more differences, causing the modification of the aircraft component to resolve the one or more differences.

Example 35 includes the method of example 31, wherein the operation is an integration of the aircraft component into the aircraft, and the method further including generating a report based on the comparisons, and after a determination that the report does not identify at least one difference, causing the integration of the aircraft component into the aircraft.

Example 36 includes the method of example 31, wherein the output is a first output, the first identifications include a first number of hole plugs, the second identifications include a second number of hole plugs, and the method further including generating a second output to be representative of a difference between the first number of hole plugs and the second number of hole plugs, determining the one or more differences based on the second output, and storing a data association of a failed verification and the aircraft component based on the one or more differences.

Example 37 includes the method of example 31, wherein the output is a first output, the first identifications include a first number of hole plugs, the second identifications include a second number of hole plugs, and the method further including generating a second output to be representative of a difference between the first number of hole plugs and the second number of hole plugs, determining that the first number of hole plugs and the second number of hole plugs is the same based on the second output, and storing a data association of a successful verification and the aircraft component based on the first number of hole plugs and the second number of hole plugs being the same.

Example 38 includes the method of example 31, wherein the output is a first output, the first identifications include a color of respective ones of the first hole plugs, the second identifications include a color of respective ones of the second hole plugs, and the method further including generating a second output to be representative of a difference between the color of the respective ones of the first hole plugs and the color of the respective ones of the second hole plugs, determining the one or more differences based on the second output, and storing a data association of a failed verification and the aircraft component based on the one or more differences.

Example 39 includes the method of example 31, wherein the output is a first output, the first identifications include a color of respective ones of the first hole plugs, the second identifications include a color of respective ones of the second hole plugs, and the method further including generating a second output to be representative of a difference between the color of the respective ones of the first hole plugs and the color of the respective ones of the second hole plugs, determining the color of the respective ones of the first hole plugs and the color of the respective ones of the second hole plugs are the same, and storing a data association of a successful verification and the aircraft component based on the color of the respective ones of the first hole plugs and the color of the respective ones of the second hole plugs being the same.

Example 40 includes the method of example 31, further including training the machine-learning model based on a plurality of images of aircraft components including hole plugs of one or more sizes and one or more colors, and after a determination that an accuracy of the machine-learning model satisfies a training threshold, storing the machine-learning model in a datastore for access by an electronic device.

Example 41 includes the method of example 31, further including training the machine-learning model to identify the aircraft component using a plurality of images of the aircraft component in different orientations or environment conditions.

Example 42 includes the method of example 31, further including training the machine-learning model to identify the first hole plugs using a plurality of images of the first hole plugs in different orientations or environment conditions.

Example 43 includes the method of example 31, wherein the output is a first output, and the method further including obtaining the second identifications of the second hole plugs based on second outputs from an automation tool plug-in, the automation tool plug-in to generate the second outputs based on the reference model as an input to the automation tool plug-in.

Example 44 includes the method of example 31, wherein the output is a first output, and the method further including determining the second identifications of the second hole plugs from second outputs of the machine-learning model based on the reference model as an input to the machine-learning model.

Example 45 includes the method of example 31, further including executing the machine-learning model to identify the aircraft component in the image.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. An apparatus comprising:
at least one memory;
machine-readable instructions; and
processor circuitry to at least one of execute or instantiate the machine-readable instructions to at least:
execute a machine-learning model based on an image of an aircraft component to generate an output representative of first identifications of first hole plugs in the aircraft component;
determine one or more differences between the first identifications of the first hole plugs in the image and second identifications of second hole plugs in a reference model of the aircraft component; and
cause an operation associated with an aircraft to occur based on the one or more differences.

2. The apparatus of claim 1, wherein the output is a first output, and the processor circuitry is to execute an optical character recognition model based on the image to generate a second output representative of a third identification of the aircraft component.

3. The apparatus of claim 2, wherein the processor circuitry is to identify the reference model in a datastore based on a data association between the third identification of the aircraft component and the reference model.

4. The apparatus of claim 1, wherein the operation is a modification of the aircraft component, and the processor circuitry is to:
generate a report based on the comparisons; and
after a determination that the report identifies the one or more differences, cause the modification of the aircraft component to resolve the one or more differences.

5. The apparatus of claim 1, wherein the operation is an integration of the aircraft component into the aircraft, and the processor circuitry is to:
generate a report based on the comparisons; and
after a determination that the report does not identify at least one difference, cause the integration of the aircraft component into the aircraft.

6. The apparatus of claim 1, wherein the output is a first output, the first identifications include a first number of hole plugs, the second identifications include a second number of hole plugs, and the processor circuitry is to:
generate a second output to be representative of a difference between the first number of hole plugs and the second number of hole plugs;
determine the one or more differences based on the second output; and
store a data association of a failed verification and the aircraft component based on the one or more differences.

7. The apparatus of claim 1, wherein the output is a first output, the first identifications include a first number of hole plugs, the second identifications include a second number of hole plugs, and the processor circuitry is to:
generate a second output to be representative of a difference between the first number of hole plugs and the second number of hole plugs;
determine that the first number of hole plugs and the second number of hole plugs is the same based on the second output; and
store a data association of a successful verification and the aircraft component based on the first number of hole plugs and the second number of hole plugs being the same.

8-15. (canceled)

16. At least one non-transitory computer readable storage medium comprising instructions that, when executed, cause processor circuitry to at least:
execute a machine-learning model based on an image of an aircraft component to generate an output representative of first identifications of first hole plugs in the aircraft component;
determine one or more differences between the first identifications of the first hole plugs in the image and second identifications of second hole plugs in a reference model of the aircraft component; and
cause an operation associated with an aircraft to occur based on the one or more differences.

17-22. (canceled)

23. The at least one non-transitory computer readable storage medium of claim 16, wherein the output is a first output, the first identifications include a color of respective ones of the first hole plugs, the second identifications include a color of respective ones of the second hole plugs, and the instructions are to cause the processor circuitry to:
generate a second output to be representative of a difference between the color of the respective ones of the first hole plugs and the color of the respective ones of the second hole plugs;
determine the one or more differences based on the second output; and
store a data association of a failed verification and the aircraft component based on the one or more differences.

24. The at least one non-transitory computer readable storage medium of claim 16, wherein the output is a first output, the first identifications include a color of respective ones of the first hole plugs, the second identifications include a color of respective ones of the second hole plugs, and the instructions are to cause the processor circuitry to:
generate a second output to be representative of a difference between the color of the respective ones of the first hole plugs and the color of the respective ones of the second hole plugs;
determine the color of the respective ones of the first hole plugs and the color of the respective ones of the second hole plugs are the same; and
store a data association of a successful verification and the aircraft component based on the color of the respective ones of the first hole plugs and the color of the respective ones of the second hole plugs being the same.

25. The at least one non-transitory computer readable storage medium of claim 16, wherein the instructions are to cause the processor circuitry to:
train the machine-learning model based on a plurality of images of aircraft components including hole plugs of one or more sizes and one or more colors; and
after a determination that an accuracy of the machine-learning model satisfies a training threshold, store the machine-learning model in a datastore for access by an electronic device.

26. The at least one non-transitory computer readable storage medium of claim 16, wherein the instructions are to cause the processor circuitry to train the machine-learning model to identify the aircraft component using a plurality of images of the aircraft component in different orientations or environment conditions.

27. The at least one non-transitory computer readable storage medium of claim 16, wherein the instructions are to cause the processor circuitry to train the machine-learning model to identify the first hole plugs using a plurality of images of the first hole plugs in different orientations or environment conditions.

28. The at least one non-transitory computer readable storage medium of claim 16, wherein the output is a first output, and the instructions are to cause the processor circuitry to obtain the second identifications of the second hole plugs based on second outputs from an automation tool plug-in, the automation tool plug-in to generate the second outputs based on the reference model as an input to the automation tool plug-in.

29. (canceled)

30. (canceled)

31. A method comprising:
executing a machine-learning model based on an image of an aircraft component to generate an output representative of first identifications of first hole plugs in the aircraft component;
determining one or more differences between the first identifications of the first hole plugs in the image and second identifications of second hole plugs in a reference model of the aircraft component; and
causing an operation associated with an aircraft to occur based on the one or more differences.

32-40. (canceled)

41. The method of claim 31, further including training the machine-learning model to identify the aircraft component using a plurality of images of the aircraft component in different orientations or environment conditions.

42. The method of claim 31, further including training the machine-learning model to identify the first hole plugs using a plurality of images of the first hole plugs in different orientations or environment conditions.

43. The method of claim 31, wherein the output is a first output, and the method further including obtaining the second identifications of the second hole plugs based on second outputs from an automation tool plug-in, the automation tool plug-in to generate the second outputs based on the reference model as an input to the automation tool plug-in.

44. The method of claim 31, wherein the output is a first output, and the method further including determining the second identifications of the second hole plugs from second outputs of the machine-learning model based on the reference model as an input to the machine-learning model.

45. The method of claim 31, further including executing the machine-learning model to identify the aircraft component in the image.
